(19) United States
(12) Patent Application Publication
(10) Pub. No.: US 2025/0173611 A1
(43) Pub. Date: May 29, 2025

(54) INFORMATION PROCESSING APPARATUS, INFERENCE APPARATUS, MACHINE-LEARNING APPARATUS, INFORMATION PROCESSING METHOD, INFERENCE METHOD, AND MACHINE-LEARNING METHOD

(71) Applicant: EBARA CORPORATION, Tokyo (JP)

(72) Inventors: Kenichi TAKEBUCHI, Tokyo (JP); Kenichiro SAITO, Tokyo (JP)

(21) Appl. No.: 18/841,820

(22) PCT Filed: Feb. 15, 2023
(86) PCT No.: PCT/JP2023/005241

§ 371 Date: Aug. 27, 2024

(30) Foreign Application Priority Data
Mar. 1, 2022 (JP) 2022-031214
Dec. 6, 2022 (JP) 2022-194728

(51) Int. Cl. G06N 20/00; B24B 37/013

(52) U.S. Cl. CPC G06N 20/00; B24B 37/013

(57) ABSTRACT

An information processing apparatus includes: an information acquisition section (500) configured to acquire finishing conditions including substrate-holder state information indicating a state of a substrate holder and a finishing-fluid-supply-structure state information indicating a state of a finishing-fluid supply structure in a finishing process of a substrate performed by a substrate processing apparatus including the substrate holder configured to hold the substrate and the finishing-fluid supply structure configured to supply a substrate finishing fluid onto the substrate; and a state prediction section (501) configured to predict substrate state information for the substrate on which the finishing process is performed under the finishing conditions by inputting the finishing conditions acquired by the information acquisition section (500) to a learning model (10A, 10B) that has been generated by machine learning that causes the learning model to learn a correlation between the finishing conditions and substrate state information indicating a state of the substrate on which the finishing process is performed under the finishing conditions.

### TECHNICAL FIELD

The present invention relates to an information processing apparatus, an inference apparatus, a machine-learning apparatus, an information processing method, an inference method, and a machine-learning method.

### BACKGROUND ART

A substrate processing apparatus that performs chemical mechanical polishing (CMP) is known as a type of substrate processing apparatuses that performs various processing on a substrate, such as a semiconductor wafer. In the substrate polishing process, for example, a substrate is chemically and mechanically polished by pressing the substrate against a polishing pad by a polishing head, which is referred to as a top ring, with a polishing liquid (e.g., slurry) being supplied onto the polishing pad from a polishing-fluid supply nozzle, while a polishing table having the polishing pad is being rotated. Then, in order to remove foreign matter, such as polishing debris adhering to the polished substrate, a cleaning tool is brought into contact with the polished substrate to scrub the polished substrate while supplying substrate cleaning fluid onto the polished substrate, and the substrate is then dried with substrate drying fluid, so that a finishing process of the substrate is completed.

In the finishing process of the substrate, stress is applied to the substrate due to stress and frictional force to the substrate when the substrate is cleaned and dried, and excessive stress may cause decrease in production quality and decrease in yield of the substrate (see, for example, Patent document 1 (paragraph [0016]) and Patent document 2 (paragraph [0006])).

### CITATION LIST

### Patent Literature

Patent document 1: Japanese laid-open patent publication No. 2003-156509
Patent document 2: Japanese laid-open patent publication No. H07-147264

### SUMMARY OF INVENTION

### Technical Problem

It is effective in controlling the production quality and the yield of the substrate if a state of the substrate, such as the stress applied to the substrate by the finishing process, during or after processing can be appropriately monitored, or if the state of the substrate can be predicted at an arbitrary timing before, during, or after processing. However, it is not realistic to directly attach some kind of sensor to each substrate in order to detect the state of the substrate. In addition, when the chemical mechanical polishing of the substrate is performed by the substrate processing apparatus, the state of the substrate fluctuates according to operating states of components (e.g., a substrate holder for holding the substrate, a finishing-fluid supplier for supplying a finishing fluid, such as substrate cleaning fluid or substrate drying fluid, to the substrate) of the substrate processing apparatus. These operating states act complexly and mutually on the substrate. Therefore, it is difficult to accurately analyze the effects of the respective operating states on the state of the substrate.

In view of the above-mentioned drawbacks, it is an object of the present invention to provide an information processing apparatus, an inference apparatus, a machine-learning apparatus, an information processing method, an inference method, and a machine-learning method capable of appropriately predicting a state of a substrate during or after a finishing process.

### Solution to Problem

In order to achieve the above object, an information processing apparatus according to one embodiment of the present invention comprises:
an information acquisition section configured to acquire finishing conditions including substrate-holder state information indicating a state of a substrate holder and a finishing-fluid-supply-structure state information indicating a state of a finishing-fluid supply structure in a finishing process of a substrate performed by a substrate processing apparatus including the substrate holder configured to hold the substrate and the finishing-fluid supply structure configured to supply a substrate finishing fluid onto the substrate; and
a state prediction section configured to predict substrate state information for the substrate on which the finishing process is performed under the finishing conditions by inputting the finishing conditions acquired by the information acquisition section to a learning model that has been generated by machine learning that causes the learning model to learn a correlation between the finishing conditions and substrate state information indicating a state of the substrate on which the finishing process is performed under the finishing conditions.

### Advantageous Effects of Invention

According to the information processing apparatus of the embodiment of the present invention, the finishing conditions including the substrate-holder state information, and the finishing-fluid-supplier state information in the finishing process of the substrate are input to the learning model, so that the substrate state information for the finishing conditions can be predicted. Therefore, the state of the substrate during or after the finishing process can be predicted appropriately.

Objects, configurations, and effects other than those described above will be made clear in detailed descriptions of the invention described below.

### BRIEF DESCRIPTION OF DRAWINGS

FIG. 1 is an overall configuration diagram showing an example of a substrate processing system 1;

FIG. 2 is a plan view showing an example of a substrate processing device 2;

FIG. 3 is a perspective view showing an example of first to fourth polishing sections 22A to 22D;

FIG. 4 is a perspective view which shows an example of first and second roll sponge cleaning sections 24A, 24B;

FIG. 5 is a perspective view which shows an example of first and second pen sponge cleaning sections 24C, 24D;

FIG. 6 is a perspective view showing an example of first and second drying sections 24E and 24F;

FIG. 7 is a block diagram showing an example of the substrate processing device 2;

FIG. 8 is a hardware configuration diagram showing an example of a computer 900;

FIG. 9 is a data configuration diagram showing an example of production history information 30 managed by a database device 3;

FIG. 10 is a data configuration diagram showing an example of a cleaning-test table 310 of finishing-test information 31 managed by the database device 3;

FIG. 10 is a data configuration diagram showing an example of a drying-test table 311 of finishing-test information 31 managed by the database device 3;

FIG. 12 is a block diagram showing a first embodiment of a machine-learning device 4;

FIG. 13 is a diagram showing an example of a first learning model 10A and first learning data 11A;

FIG. 14 is a diagram showing an example of a second learning model 10B and second learning data 11B;

FIG. 15 is a flowchart showing an example of a machine-learning method performed by the machine-learning apparatus 4;

FIG. 16 is a block diagram showing an example of an information processing device 5 according to a first embodiment;

FIG. 17 is a function illustrating diagram of an example of the information processing device 5 according to the first embodiment;

FIG. 18 is a flowchart showing an example of an information processing method performed by the information processing device 5;

FIG. 19 is a block diagram showing an example of a machine-learning apparatus 4a according to a second embodiment;

FIG. 20 is a diagram showing an example of a third learning model 10C and third learning data 11C;

FIG. 21 is a diagram showing an example of a fourth learning model 10D and fourth learning data 11D;

FIG. 22 is a block diagram showing an example of an information processing device 5a according to the second embodiment;

FIG. 23 is a function illustrating diagram showing an example of the information processing device 5a according to the second embodiment;

FIG. 24 is a block diagram showing an example of a machine-learning device 4b according to the third embodiment;

FIG. 25 is a diagram showing an example of a fifth learning model 10E and fifth learning data IE for cleaning-quality analysis;

FIG. 26 is a diagram showing an example of a sixth learning model 10F and sixth learning data 11F for drying-quality analysis;

FIG. 26 is a block diagram showing an example of an information processing device 5b according to the third embodiment; and

FIG. 28 is a function illustrating diagram showing an example of the information processing device 5b according to the third embodiment.

### DESCRIPTION OF EMBODIMENTS

Embodiments for practicing the present invention will be described below with reference to the drawings. In the following descriptions, scope necessary for the descriptions to achieve the object of the present invention will be schematically shown, scope necessary for the descriptions of relevant parts of the present invention will be mainly described, and parts omitted from the descriptions will be based on known technology.

### First Embodiment

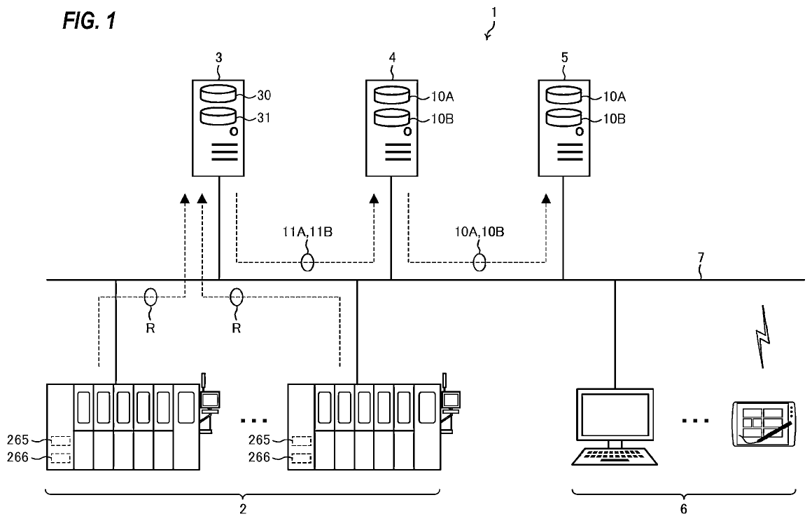

FIG. 1 is an overall configuration diagram showing an example of a substrate processing system 1. The substrate processing system 1 according to the present embodiment functions as a system configured to manage a series of substrate processes including a chemical mechanical polishing (hereinafter referred to as “polishing process”) of planarizing a surface of a substrate (hereinafter referred to as a “wafer”) W, such as a semiconductor wafer, by pressing the wafer W against a polishing pad, a cleaning process of cleaning the surface of the wafer W after the polishing process by bringing the wafer W into contact with a cleaning tool, and a drying process of drying the cleaned substrate.

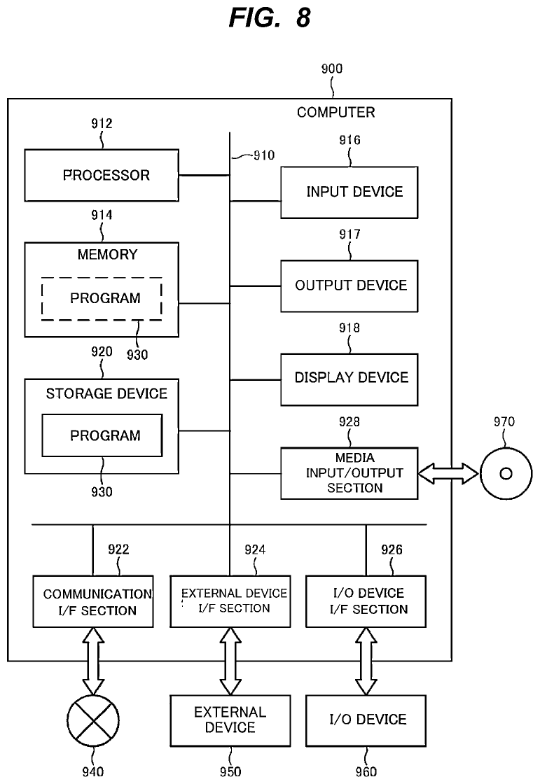

The substrate processing system 1 includes, as its main components, substrate processing devices 2, a database device 3, a machine-learning device 4, an information processing device 5, and a user terminal device 6. Each of the devices 2 to 6 is configured with, for example, a general-purpose computer or dedicated computer (see FIG. 8 described later). The devices 2 to 6 are coupled to a wired or wireless network 7 so as to be able to transmit and receive various data (some data are shown in FIG. 1 with dotted arrows). The number of devices 2 to 6 and the connection configuration of the network 7 are not limited to the example shown in FIG. 1, and may be changed as appropriate.

Each substrate processing device 2 is composed of a plurality of units and is configured to perform a series of substrate processes on one or more wafers W, such as loading, polishing, cleaning, drying, film-thickness measuring, and unloading. During the processes, the substrate processing device 2 controls operations of the units while referring to device setting information 265 including device parameters that have been set for the units and substrate recipe information 266 that determines operating conditions in the polishing process, the cleaning process, and the drying process.

The substrate processing device 2 is configured to transmit various reports R to the database device 3, the user terminal device 6, etc. according to the operation of each unit. The various reports R include, for example, process information that identifies a wafer W on which substrate processing is performed, device-state information that indicates a state of each unit when each process is performed, event information detected by the substrate processing device 2, and manipulation information of a user (an operator, a production manager, a maintenance manager, etc.) on the substrate processing device 2.

The database device 3 is an apparatus that manages production history information 30 on a history when substrate processing is performed on a wafer W for proper production, and finishing-test information 31 on a history of a test of finishing process (hereinafter referred to as “finishing test”) that has been performed on a dummy wafer for test. The finishing process is a process of finishing the surface to be finished of the wafer W after the polishing process, and includes, for example, the cleaning process, the drying process, and the like. In this embodiment, a case will be described in which the cleaning process and the drying process are performed as the finishing process, and a test of cleaning process (hereinafter referred to as “cleaning test”) and a test of drying process (hereinafter referred to as “drying test”) are performed as the finishing test. In addition to the above information, the database device 3 may also store the device setting information 265 and the substrate recipe information 266. In that case, the substrate processing device 2 may refer to these information.

The database device 3 receives various reports R from the substrate processing device 2 when the substrate processing device 2 has performed the substrate processing on the wafer W for proper production, and registers the various reports R in the production history information 30, so that the reports R on the substrate processing are accumulated in the production history information 30.

When the substrate processing device 2 performs the finishing test on the dummy wafer for test, the database device 3 receives the various reports R (including at least the device-state information) from the substrate processing device 2, registers the reports R in the finishing-test information 31, and registers test results of the finishing test associated with the various reports R, so that the reports R and the test results on the finishing test are accumulated in the finishing-test information 31. The dummy wafer is a tool imitating the wafer W. Dummy-wafer sensors, such as a pressure sensor and a temperature sensor, are disposed on a surface of the dummy wafer or in the dummy wafer, and are each configured to measure a state of the wafer W when the finishing process is performed on the wafer W. Measurement values of the dummy-wafer sensors are registered as the test results in the finishing-test information 31. The dummy-wafer sensor(s) may be disposed at one or a plurality of portions of a substrate surface of the dummy wafer, or may be disposed in a planar arrangement. The finishing test may be performed by the substrate processing device 2 for proper production, or may be performed by a finishing-test device (e.g., a cleaning-test device for performing a cleaning test, or a drying-test device for performing a drying test) for testing capable of performing the same finishing process as that of the substrate processing device 2.

The machine-learning device 4 operates as a main configuration for a learning phase in machine learning. For example, the machine-learning device 4 acquires, as first and second learning data 11A and 11B, part of the finishing-test information 31 from the database device 3, and performs the machine learning to create a first and second learning models 10A and 10B to be used in the information processing device 5. The first and second learning models 10A and 10B as learned models are provided to the information processing device 5 via the network 7, a storage medium, or the like.

The information processing device 5 operates as a main configuration for an inference phase in the machine learning. When the finishing process is performed on a wafer W for proper production by the substrate processing device 2, the information processing device 5 predicts a state of the wafer W using the first and second learning models 10A and 10B created by the machine-learning device 4, and transmits substrate state information, which is a result of the prediction, to the database device 3, the user terminal device 6, etc. The timing at which the information processing device 5 predicts the substrate state information may be after the finishing process (i.e., post-predicting process), during the finishing process (i.e., real-time-predicting process), or before the finishing process (i.e., pre-predicting process).

The user terminal device 6 is a terminal device used by a user. The user terminal device 6 may be a stationary device or a portable device. The user terminal device 6 receives various input manipulations via a display screen of an application program, a web browser, etc., and displays various information (e.g., a notification of event, the substrate state information, the production history information 30, the finishing-test information 31, etc.) via the display screen.

### (Substrate Processing Device 2)

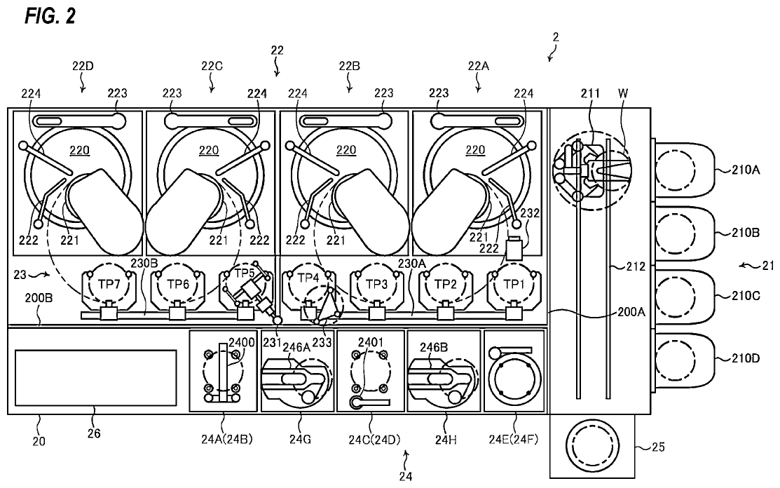

FIG. 2 is a plan view showing an example of the substrate processing device 2. The substrate processing device 2 includes a load-unload unit 21, a polishing unit 22, a substrate transport unit 23, a finishing unit 24, a film-thickness measuring unit 25, and a control unit 26 which are arranged inside a housing 20 that is substantially rectangular in a plan view. The load-unload unit 21 is isolated from the polishing unit 22, the substrate transport unit 23, and the finishing unit 24 by a first partition wall 200A. The substrate transport unit 23 is isolated from the finishing unit 24 by a second partition wall 200B.

### (Load-Unload Unit)

The load-unload unit 21 includes first to fourth front load sections 210A to 210D on which wafer cassettes (FOUPs, etc.), each capable of storing a large number of wafers W along a vertical direction, are placed, a transfer robot 211 that is movable along the storage direction (vertical direction) of the wafers W in each wafer cassette, and a horizontally-moving mechanism 212 for moving the transfer robot 211 along an arrangement direction of the first to fourth front load sections 210A to 210D (i.e., along a direction of a shorter side of the housing 20).

The transfer robot 211 is configured to be accessible to the wafer cassette placed on each of the first to fourth front load sections 210A to 210D, the substrate transport unit 23 (specifically, a lifter 232, which will be described later), the finishing unit 24 (specifically, first and second drying section 24E, 24F, which will be described later), and the film-thickness measuring unit 25. The transfer robot 211 includes upper and lower hands (not shown) for transporting the wafer W between the wafer cassette, the substrate transport unit 23, the finishing unit 24, and the film-thickness measuring unit 25. The lower hand is used when transporting the wafer W before processing of the wafer W, and the upper hand is used when transporting the wafer W after processing of the wafer W. When the wafer W is transported to and from the substrate transport unit 23 or the finishing unit 24, a shutter (not shown) provided on the first partition wall 200A is opened and closed.

### (Polishing Unit)

The polishing unit 22 includes first to fourth polishing sections 22A to 22D each configured to perform the polishing process (planarization) on the wafer W. The first to fourth polishing sections 22A to 22D are arranged in parallel along the longitudinal direction of the housing 20.

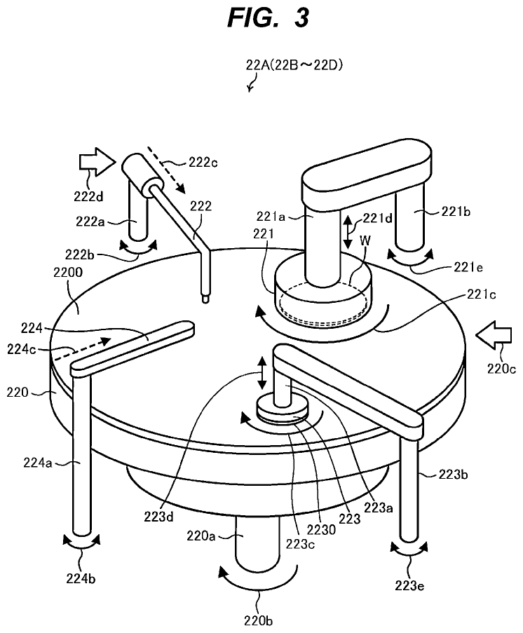

FIG. 3 is a perspective view showing an example of the first to fourth polishing sections 22A to 22D. The first to fourth polishing sections 22A to 22D have common basic configurations and functions.

Each of the first to fourth polishing sections 22A to 22D includes a polishing table 220 that rotatably supports a polishing pad 2200 having a polishing surface, a top ring (polishing head) 221 configured to hold the wafer W and to polish the wafer W while pressing the wafer W against the polishing pad 2200 on the polishing table 220, a polishing-fluid supply nozzle 222 configured to supply a polishing fluid onto the polishing pad 2200, a dresser 223 that rotatably supports a dresser disk 2230 and configured to dress the polishing pad 2200 by bringing the dresser disk 2230 into contact with the polishing surface of the polishing pad 2200, and an atomizer 224 configured to emit a cleaning fluid to the polishing pad 2200.

The polishing table 220 is supported by a polishing table shaft 220a. The polishing table 220 includes a rotating mechanism 220b configured to rotate the polishing table 220 about its own axis, and a temperature regulating mechanism 220c configured to regulate a surface temperature of the polishing pad 2200.

The top ring 221 is supported by a top-ring shaft 221a that is movable in the vertical direction. The top ring 221 includes a rotating mechanism 221c configured to rotate the top ring 221 about an axis of the top ring 221, a vertical movement mechanism 221d configured to move the top ring 221 in the vertical direction, and an oscillation mechanism 221e configured to rotate (or oscillate) the top ring 221 around a support shaft 221b as a pivot center.

The polishing-fluid supply nozzle 222 is supported by a support shaft 222a. The polishing-fluid supply nozzle 222 includes an oscillation mechanism 222b configured to rotate and move the polishing-fluid supply nozzle 222 around the support shaft 222a as a pivot center, a flow-rate regulator 222c configured to regulate a flow rate of the polishing fluid, and a temperature regulating mechanism 222d configured to regulate a temperature of the polishing fluid. The polishing fluid is a polishing liquid (e.g., slurry) or pure water, which may further include a chemical liquid, or may be a polishing liquid to which a dispersant is added.

The dresser 223 is supported by a dresser shaft 223a that is movable in the vertical direction. The dresser 223 includes a rotating mechanism 223c configured to rotate about its own axis, a vertical movement mechanism 223d configured to move the dresser 223 in the vertical direction, and an oscillation mechanism 223e configured to rotate and move the dresser 223 around a support shaft 223b as a pivot center.

The atomizer 224 is supported by a support shaft 224a. The atomizer 224 includes an oscillation mechanism 224b configured to rotate and move the atomizer 224 around the support shaft 224a as a pivot center, and a flow-rate regulator 224c configured to regulate a flow rate of the cleaning fluid. The cleaning fluid is a mixture of liquid (e.g., pure water) and gas (e.g., nitrogen gas), or liquid (e.g., pure water).

The wafer W is attracted and held on the lower surface of the top ring 221 and is moved to a predetermined polishing position above the polishing table 220. Thereafter, the wafer W is polished by being pressed by the top ring 221 against the polishing surface of the polishing pad 2200 on which the polishing fluid is supplied from the polishing-fluid supply nozzle 222.

### (Substrate Transport Unit)

As shown in FIG. 2, the substrate transport unit 23 includes first and second linear transporters 230A, 230B that are horizontally movable along the arrangement direction of the first to fourth polishing sections 22A to 22D (i.e., the longitudinal direction of the housing 20), a swing transporter 231 arranged between the first and second linear transporters 230A, 230B, a lifter 232 arranged near the load-unload unit 21, and a temporary station 233 for the wafer W arranged near the finishing unit 24.

The first linear transporter 230A is arranged adjacent to the first and second polishing sections 22A and 22B and is configured to transport the wafer W to four transfer positions (which will be referred to as first to fourth transfer positions TP1 to TP4 in the order from the load-unload-unit-21-side). The second transfer position TP2 is a position where the wafer W is delivered to the first polishing section 22A, and the third transfer position TP3 is a position where the wafer W is delivered to the second polishing section 22B.

The second linear transporter 230B is arranged adjacent to the third and fourth polishing sections 22C and 22D and is configured to transport the wafer W to three transfer positions (which will be referred to as fifth to seventh transfer positions TP5 and TP7 in the order from the load-unload-unit-21-side). The sixth transfer position TP6 is a position where the wafer W is delivered to the third polishing section 22C, and the seventh transfer position TP7 is a position where the wafer W is delivered to the fourth polishing section 22D.

The swing transporter 231 is disposed adjacent to the fourth and fifth transfer positions TP4 and TP5. The swing transporter 231 has a hand that is movable between the fourth and fifth transfer positions TP4 and TP5. The swing transporter 231 is configured to transport the wafer W between the first and second linear transporters 230A and 230B and place the wafer W temporarily on the temporary station 233. The lifter 232 is disposed adjacent to the first transfer position TP1. The lifter 232 is configured to transport the wafer W between the first transfer position TP1 and the transfer robot 211 of the load-unload unit 21. When the wafer W is transported, the shutter (not shown) provided on the first partition wall 200A is opened and closed.

### (Finishing Unit)

As shown in FIG. 2, the finishing unit 24 includes a substrate cleaning device using roll sponge 2400 that includes first and second roll sponge cleaning sections 24A and 24B arranged in upper and lower stages. The finishing unit 24 further includes a substrate cleaning device using pen sponge 2401 that includes first and second pen sponge cleaning sections 24C and 24D arranged in upper and lower stages. The finishing unit 24 further includes a substrate drying device for dying the cleaned wafer W that includes first and second drying sections 24E and 24F arranged in upper and lower stages. The finishing unit 24 further includes first and second transport sections 24G and 24H configured to transport the wafer W. It is noted that the number and arrangement of the roll sponge cleaning sections 24A, 24B, the pen sponge cleaning sections 24C, 24D, the drying sections 24E, 24F, and the transport sections 24G, 24H are not limited to the example in FIG. 2, and may be changed as appropriate.

The sections 24A to 24H of the finishing unit 24 are isolated from each other and are arranged along the first and second linear transporters 230A and 230B, for example, in an order of the first and second roll sponge cleaning sections 24A, 24B, the first transport section 24G, the first and second pen sponge cleaning sections 24C, 24D, the second transport section 24H, and the first and second drying sections 24E, 24F (in an order of distance from the load-unload unit 21). The finishing unit 24 sequentially performs a primary cleaning process on the wafer W after the polishing process using one of the first and second roll sponge cleaning sections 24A and 24B, a secondary cleaning process on the wafer W using one of the first and second pen sponge cleaning section 24C and 24D, and a drying process on the wafer W using one of the first and second drying sections 24E and 24F.

The roll sponges 2400 and the pen sponges 2401 are made of synthetic resin, such as PVA or nylon, and have a porous structure. The roll sponges 2400 and the pen sponges 2401 function as cleaning tools for scrubbing the wafer W. The roll sponges 2400 and the pen sponges 2401 are removably attached to the first and second roll sponge cleaning sections 24A, 24B and the first and second pen sponge cleaning sections 24C, 24D, respectively.

The first transport section 24G includes therein a first transfer robot 246A that is movable in the vertical direction. The first transfer robot 246A is configured to be able to access the temporary station 233 of the substrate transport unit 23, the first and second roll sponge cleaning sections 24A, 24B, and the first and second pen sponge cleaning sections 24C, 24D, and has upper and lower hands (not shown) configured to transport the wafer W between them. For example, the lower hand is used to transport the wafer W before cleaning of the wafer W, and the upper hand is used to transport the wafer W after cleaning of the wafer W. When the wafer W is transported from the temporary station 233, a shutter (not shown) provided on the second partition wall 200B is opened and closed.

The second transport section 24H includes a second transfer robot 246B that is movable in the vertical direction. The second transfer robot 246B is configured to be accessible to the first and second pen sponge cleaning sections 24C, 24D and the first and second drying sections 24E, 24F, and has a hand (not shown) configured to transport the wafer W between them.

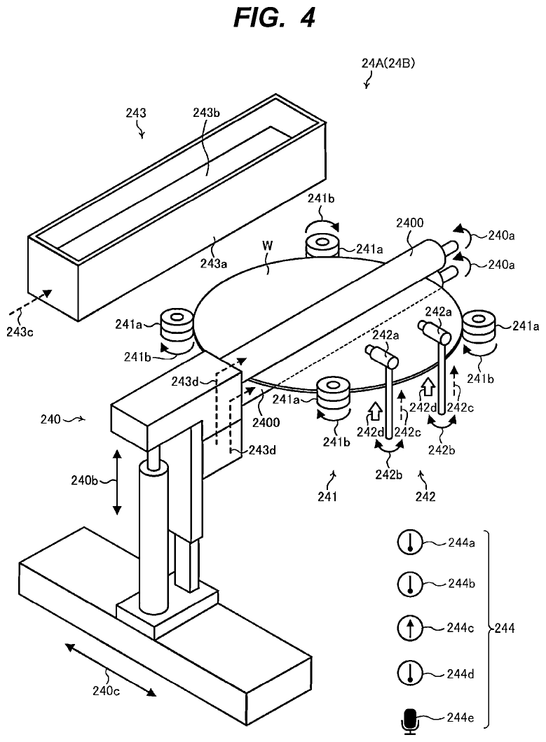

FIG. 4 is a perspective view showing an example of the first and second roll sponge cleaning sections 24A and 24B. Basic configurations and functions of the first and second roll sponge cleaning sections 24A and 24B are common. In the example of FIG. 4, the first and second roll sponge cleaning sections 24A and 24B have a pair of roll sponges 2400 arranged one above the other so as to sandwich surfaces to be cleaned (front and back surfaces) of the wafer W.

Each of the first and second roll sponge cleaning sections 24A and 24B includes a substrate holder 241 configured to hold the wafer W, a cleaning-fluid supply structure 242 configured to supply substrate cleaning fluid onto the wafer W, a substrate cleaning structure 240 configured to rotatably support the roll sponges 2400 and clean the wafer W by bringing the roll sponges 2400 in contact with the wafer W, a cleaning-tool cleaning structure 243 configured to clean (self-clean) the roll sponges 2400 with a cleaning-tool cleaning fluid, and environmental sensors 244 configured to measure a condition of an internal space of the housing 20 where the cleaning process is performed. The cleaning-fluid supply structure 242 corresponds to a finishing-fluid supply structure configured to supply the substrate cleaning fluid as a substrate finishing fluid.

The substrate holder 241 includes substrate holding mechanisms 241a configured to hold multiple portions of the side edge of the wafer W, and substrate rotating mechanisms 241b configured to rotate the wafer W about a first rotation axis perpendicular to the cleaning target surface of the wafer W. In the example of FIG. 4, the substrate holding mechanisms 241a include four rollers. At least one of the rollers is configured to be movable in a holding direction or a releasing direction with respect to the side edge of the wafer W. The substrate rotating mechanism 241b drives and rotates at least one roller.

The cleaning-fluid supply structure 242 includes cleaning-fluid supply nozzles 242a configured to supply substrate cleaning fluid to the cleaning target surface of the wafer W, swing movement mechanisms 242b configured to swing and move the cleaning-fluid supply nozzles 242a, flow-rate regulators 242c configured to regulate flow rate and pressure of the substrate cleaning fluid, and a temperature regulating mechanism 242d configured to regulate temperature of the substrate cleaning fluid. The substrate cleaning fluid may be either pure water (rinsing liquid), or a chemical liquid, or mixture of the pure water and the chemical liquid (for example, a concentration can be adjusted by adjusting flow rates of the pure water and the chemical liquid by the flow-rate regulators 242c). The cleaning-fluid supply nozzles 242a may be a nozzle for pure water and a nozzle for chemical liquid which are arranged separately, as shown in FIG. 4. Further, the substrate cleaning fluid may be a liquid, a two-fluid mixture of a liquid and a gas, or a fluid containing a solid, such as dry ice.

The substrate cleaning structure 240 includes cleaning-tool rotating mechanisms 240a configured to rotate the roll sponges 2400 about second rotation axes parallel to the cleaning target surface of the wafer W, a vertical movement mechanism 240b configured to move at least one of the pair of roll sponges 2400 in the vertical direction so as to change heights of the roll sponges 2400 and a distance between the roll sponges 2400. The vertical movement mechanism 240b and the linear movement mechanism 240c function as a cleaning-tool movement mechanism configured to move the relative position of the roll sponges 2400 and the cleaning target surface of the wafer W.

The cleaning-tool cleaning structure 243 is arranged in a position that does not interfere with the wafer W. The cleaning-tool cleaning structure 243 includes a cleaning-tool cleaning tank 243a that can store and discharge cleaning-tool cleaning fluid, a cleaning-tool cleaning plate 243b disposed in the cleaning-tool cleaning tank 243a such that the roll sponge 2400 can be pressed against the cleaning-tool cleaning plate 243b, a flow-rate regulator 243c configured to regulate flow rate and pressure of the cleaning-tool cleaning fluid supplied to the cleaning-tool cleaning tank 243a, and a flow-rate regulator 243c configured to regulate flow rate and pressure of the cleaning-tool cleaning fluid flowing in the roll sponge 2400 and discharged through an outer circumferential surface of the roll sponge 2400 to the outside. The cleaning-tool cleaning fluid may be either pure water (rinsing liquid), or a chemical liquid, or mixture of the pure water and the chemical liquid (for example, a concentration can be adjusted by adjusting flow rates of the pure water and the chemical liquid by the flow-rate regulators 243c)

The environment sensors 244 include, for example, a temperature sensor 244a, a humidity sensor 244b, an atmospheric-pressure sensor 244c, an oxygen concentration sensor 244d, and a microphone (sound sensor) 244e. The environment sensors 244 may include a camera (image sensor) capable of generating an image of the surface of the wafer W or the roll sponge 2400, temperature distribution, air-flow distribution, or the like during or before or after the cleaning process. The object of the camera is not limited to visible light, and may be infrared light, ultraviolet light, or the like.

The first and second roll sponge cleaning sections 24A and 24B perform the primary cleaning process. Specifically, the wafer W is rotated by the substrate rotating mechanism 241b while the wafer W is held by the substrate holding mechanism 241a. Then, the substrate cleaning fluid is supplied from the cleaning-fluid supply nozzles 242a to the cleaning target surfaces of the wafer W. The roll sponges 2400 are rotated around their own axes by the cleaning-tool rotating mechanisms 240a and are placed in sliding contact with the cleaning target surfaces of the wafer W. The wafer W is cleaned by the sliding contact with the roll sponges 2400. Thereafter, the substrate cleaning structure 240 moves the roll sponge 2400 into the cleaning-tool cleaning tank 243a, where the roll sponge 2400 is rotated, or pressed against the cleaning-tool cleaning plate 243b, or supplied with the cleaning-tool cleaning fluid by the flow-rate regulator 243d, so that the roll sponge 2400 is cleaned.

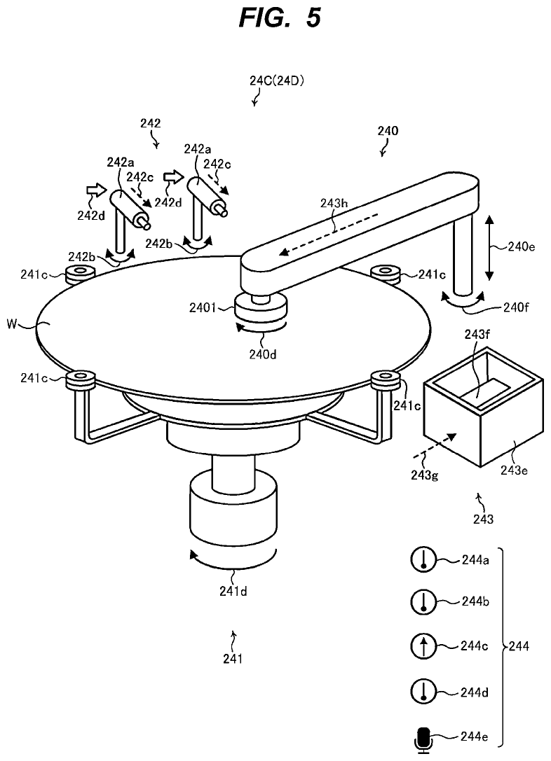

FIG. 5 is a perspective view showing an example of the first and second pen sponge cleaning sections 24C and 24D. Basic configurations and functions of the first and second pen sponge cleaning sections 24C and 24D are common.

Each of the first and second pen sponge cleaning sections 24C and 24D includes a substrate holder 241 configured to hold the wafer W, a cleaning-fluid supply structure 242 configured to supply substrate cleaning fluid onto the wafer W, a substrate cleaning structure 240 configured to rotatably support the pen sponge 2401 and clean the wafer W by bringing the pen sponge 2401 in contact with the wafer W, a cleaning-tool cleaning structure 243 configured to clean (self-clean) the pen sponge 2401 with a cleaning-tool cleaning fluid, and environmental sensors 244 configured to measure a condition of an internal space of the housing 20 where the cleaning process is performed. The cleaning-fluid supply structure 242 corresponds to a finishing-fluid supply structure configured to supply the substrate cleaning fluid as the substrate finishing fluid. The following describes are focused on configurations of the pen sponge cleaning sections 24C and 24D different from the roll sponge cleaning sections 24A and 24B.

The substrate holder 241 includes a substrate holding mechanism 241c configured to hold multiple portions of the side edge of the wafer W, and a substrate rotating mechanism 241d configured to rotate the wafer W about a first rotation axis perpendicular to the cleaning target surface of the wafer W. In the example of FIG. 5, the substrate holding mechanisms 241c include four chucks, and at least one of the four chucks is configured to be movable in a holding direction or a releasing direction with respect to the side edge of the wafer W. The substrate rotating mechanism 241d is configured to rotate support shafts coupled to the four chucks.

The cleaning-fluid supply structure 242 has the same configurations as that shown in FIG. 4, and includes cleaning-fluid supply nozzles 242a, swing movement mechanisms 242b, flow-rate regulators 242c, and temperature regulating mechanisms 242d.

The substrate cleaning structure 240 includes a cleaning-tool rotating mechanism 240d configured to rotate the pen sponge 2401 about a third rotation axis perpendicular to the cleaning target surface of the wafer W, a vertical movement mechanism 240e configured to move the pen sponge 2401 in the vertical direction, and a swing movement mechanism 240f configured to swing and move the pen sponge 2401 in the horizontal direction. The vertical movement mechanism 240e and the swing movement mechanism 240f function as a cleaning-tool movement mechanism configured to move the relative position of the pen sponge 2401 and the cleaning target surface of the wafer W.

The cleaning-tool cleaning structure 243 is arranged in a position that does not interfere with the wafer W. The cleaning-tool cleaning structure 243 includes a cleaning-tool cleaning tank 243e that can store and discharge cleaning-tool cleaning fluid, a cleaning-tool cleaning plate 243f disposed in the cleaning-tool cleaning tank 243e such that the pen sponge 2401 can be pressed against the cleaning-tool cleaning plate 243f, a flow-rate regulator 243g configured to regulate flow rate and pressure of the cleaning-tool cleaning fluid supplied to the cleaning-tool cleaning tank 243e, and a flow-rate regulator 243h configured to regulate flow rate and pressure of the cleaning-tool cleaning fluid flowing in the pen sponge 2401 and discharged through an outer circumferential surface of the pen sponge 2401 to the outside.

The environment sensors 244 include, for example, a temperature sensor 244a, a humidity sensor 244b, an atmospheric-pressure sensor 244c, an oxygen concentration sensor 244d, and a microphone (sound sensor) 244e. The environment sensors 244 may include a camera (image sensor) capable of generating an image of the surface of the wafer W or the pen sponge 2401, temperature distribution, air-flow distribution, or the like during or before or after the cleaning process. The object of the camera is not limited to visible light, and may be infrared light, ultraviolet light, or the like.

The first and second pen sponge cleaning sections 24C and 24D perform the secondary cleaning process. Specifically, the wafer W is rotated by the substrate rotating mechanism 241d while the wafer W is held by the substrate holding mechanism 241c. Then, the substrate cleaning fluid is supplied from the cleaning-fluid supply nozzles 242a to the cleaning target surface of the wafer W. The pen sponge 2401 is rotated around its own axis by the cleaning-tool rotating mechanisms 240d and is placed in sliding contact with the cleaning target surface of the wafer W. The wafer W is cleaned by the sliding contact with the pen sponge 2401. Thereafter, the substrate cleaning structure 240 moves the pen sponge 2401 into the cleaning-tool cleaning tank 243e, where the pen sponge 2401 is rotated, or pressed against the cleaning-tool cleaning plate 243f, or supplied with the cleaning-tool cleaning fluid by the flow-rate regulator 243h, so that the pen sponge 2401 is cleaned.

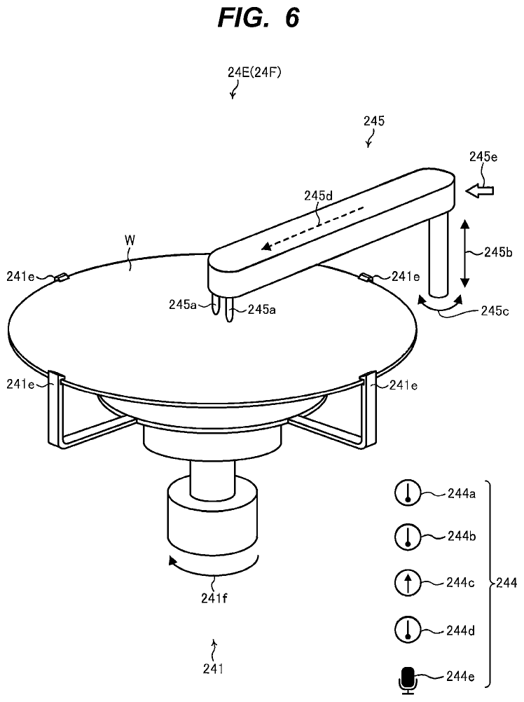

FIG. 6 is a perspective view showing an example of the first and second drying sections 24E and 24F. Basic configurations and functions of the first and second drying sections 24E and 24F are common.

Each of the first and second drying sections 24E and 24F includes a substrate holder 241 configured to hold the wafer W, a drying-fluid supply structure 245 configured to supply substrate drying fluid to the wafer W, a housing 20 where the drying process is performed, and environment sensors 244 configured to measure a condition of an internal space of the housing 20 where the drying process is performed. The drying-fluid supply structure 245 corresponds to the finishing-fluid supply structure configured to supply the substrate drying fluid as the substrate finishing fluid.

The substrate holder 241 includes substrate holding mechanisms 241e configured to hold multiple portions of the side edge of the wafer W, and a substrate rotating mechanism 241f configured to rotate the wafer W about a first rotation axis perpendicular to the cleaning target surface of the wafer W.

The drying-fluid supply structure 245 includes drying-fluid supply nozzles 245a configured to supply substrate drying fluid onto the cleaning target surface of the wafer W, a vertical movement mechanism 245b configured to move the drying-fluid supply nozzles 245a in the vertical direction, a swing movement mechanism 245c configured to swing and move the drying-fluid supply nozzles 245a in the horizontal direction, a flow-rate regulator 245d configured to regulate flow rate and pressure of the substrate drying fluid, and a temperature regulating mechanism 245e configured to regulate a temperature of the substrate drying fluid. The vertical movement mechanism 245b and the swing movement mechanism 245c function as a drying-fluid supply nozzle movement mechanism configured to move a relative position of the drying-fluid supply nozzles 245a and the cleaning target surface of the wafer W. The substrate drying fluid is, for example, IPA vapor and pure water (rinsing liquid). The drying-fluid supply nozzles 245a have a nozzle for IPA vapor and a nozzle for pure water provided separately, as shown in FIG. 6. Furthermore, the substrate drying fluid may be a liquid, a two-fluid mixture of a liquid and a gas, or a fluid containing a solid, such as dry ice.

The environment sensors 244 include, for example, a temperature sensor 244a, a humidity sensor 244b, an atmospheric-pressure sensor 244c, an oxygen concentration sensor 244d, and a microphone (sound sensor) 244e. The environment sensors 244 may include a camera (image sensor) capable of generating an image of the surface of the wafer W, temperature distribution, air-flow distribution, or the like during or before or after the drying process. The object of the camera is not limited to visible light, and may be infrared light, ultraviolet light, or the like.

The first and second drying sections 24E and 24F are configured to perform the drying process. Specifically, the wafer W is rotated by the substrate rotating mechanism 241f while the wafer W is held by the substrate holding mechanisms 241e. Then, the substrate drying fluid is supplied from the drying-fluid supply nozzles 245a onto the cleaning target surface of the wafer W, while the drying-fluid supply nozzles 245a are moved toward the side edge of the wafer W (in the radially outward direction). Thereafter, the wafer W is dried by being rotated at high speed by the substrate rotating mechanism 241f.

In FIGS. 4 to 6, detailed configurations of the substrate rotating mechanisms 241b, 241d, the vertical movement mechanisms 240b, 240e, 245b, the linear movement mechanism 240c, and the swing movement mechanisms 240f, 242b, 245c, and the cleaning-tool rotating mechanisms 240a, 240d are omitted, but they may include a module for generating driving force (e.g., a motor or an air cylinder), a driving force transmission mechanism (e.g., a linear guide, a ball screw, a gear, a belt, a coupling, a bearing, etc.), and sensor (e.g., a linear sensor, an encoder sensor, a limit sensor, a torque sensor, etc.), which may be appropriately combined. In FIGS. 4 to 6, the specific configurations of the flow-rate regulators 243c, 243d, 243g, 243h, and 245d are omitted, but they may include a module for fluid regulation (e.g., a pump, a valve, a regulator, etc.) and sensor (e.g., a flow-rate sensor, a pressure sensor, a liquid level sensor, a temperature sensor, a fluid-concentration sensor, fluid particle sensor, etc.), which may be appropriately combined. In FIGS. 4 to 6, the specific configurations of the temperature regulating mechanisms 242d and 245e are omitted, but they may include a contact type or non-contact type module for temperature regulation (e.g., a heater, a heat exchanger, etc.) and sensor (a temperature sensor, an electric current sensor, etc.).

### (Film-Thickness Measuring Unit)

The film-thickness measuring unit 25 is a measuring device that measures the film thickness of the wafer W before or after the polishing process. The film-thickness measuring unit 25 is, for example, an optical film-thickness measuring device, an eddy current type film-thickness measuring device, or the like. The transfer robot 211 transports the wafer W to and from each film-thickness measuring module.

### (Control Unit)

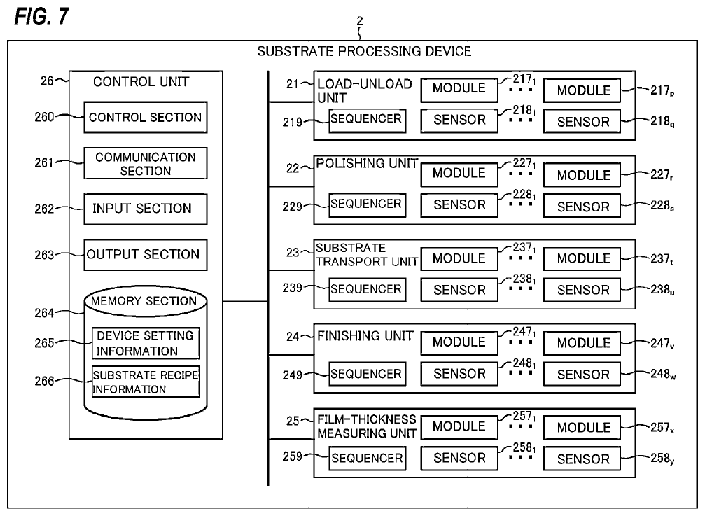

FIG. 7 is a block diagram showing an example of the substrate processing device 2. The control unit 26 is electrically coupled to each of the units 21 to 25, and functions as a control section that comprehensively controls the units 21 to 25. In this embodiment, a control system (i.e., modules, sensors, and a sequencer) of the finishing unit 24 will be described as an example. Control systems of the other units 21 to 23 and 25 have common basic configurations and functions, and descriptions will be omitted.

The finishing unit 24 includes modules 2471 to 247r to be controlled, which are disposed in sub-units (e.g., the first and second roll sponge cleaning sections 24A, 24B, the first and second pen sponge cleaning sections 24C, 24D, the first and second drying sections 24E, 24F, the first and second transport sections 24G, 24H, etc.), respectively, sensors 2481 to 248s arranged in the modules 2471 to 247r, respectively, for detecting data (i.e., detection values) necessary for controlling the modules 2471 to 247r, and a sequencer 249 for controlling the operations of the modules 2471 to 247r based on the detection values obtained by the sensors 2481 to 248s.

Examples of the sensors 2481 to 248s of the finishing unit 24 include a sensor configured to detect a holding pressure when the substrate holding mechanism 241a, 241c holds the substrate, a sensor configured to detect a rotation speed of the substrate holding mechanism 241a, 241c, a sensor configured to detect a rotation torque of the substrate rotation mechanism 241b, 241d, a sensor configured to detect a flow rate of the substrate cleaning fluid or the substrate drying fluid, a sensor configured to detect a pressure of the substrate cleaning fluid or the substrate drying fluid, a sensor configured to detect position coordinates of the cleaning-fluid supply structure 242 or the drying-fluid supply structure 245 that can be converted into a dropping position of the substrate cleaning fluid or the substrate drying fluid, a sensor configured to detect a temperature of the substrate cleaning fluid or the substrate drying fluid, a sensor configured to detect a concentration of the substrate cleaning fluid or the substrate drying fluid, a sensor configured to detect a rotation speed of the cleaning-tool rotating mechanisms 240a, a sensor configured to detect a rotation torque of the cleaning-tool rotating mechanisms 240a, a sensor configured to detect position coordinates of the cleaning-tool moving mechanism (the vertical movement mechanism 240b, 240e, the linear movement mechanism 240c, the swing movement mechanism 240f), a sensor configured to detect a movement speed of the cleaning-tool moving mechanism, a sensor configured to detect a movement torque of the cleaning-tool moving mechanism, a sensor configured to detect a pressing load when the cleaning tool (the roll sponge 2400, the pen sponge 2401) is brought into contact with the wafer W or the cleaning-tool cleaning plate 243b, 243f, a sensor configured to detect a flow rate of the cleaning-tool cleaning fluid, a sensor configured to detect a pressure of the cleaning-tool cleaning fluid, a sensor configured to detect cleanliness of the cleaning-tool cleaning fluid (for example, particles contained in a waste liquid of the cleaning-tool cleaning tank 243a, 243e), and the environmental sensor 244.

The control unit 26 includes a control section 260, a communication section 261, an input section 262, an output section 263, and a storage section 264. The control unit 26 is comprised of, for example, a general-purpose or dedicated computer (see FIG. 8, which will be described later).

The communication section 261 is coupled to the network 7 and functions as a communication interface for transmitting and receiving various data. The input section 262 receives various input operations. The output section 263 functions as a user interface by outputting various information via a display screen, lighting of signal tower, or buzzer sound.

The memory section 264 stores therein various programs (operating system (OS), application programs, web browser, etc.) and data (the device setting information 265, the substrate recipe information 266, etc.) used in the operations of the substrate processing device 2. The device setting information 265 and the substrate recipe information 266 are data that can be edited by the user via the display screen.

The control section 260 obtains detection values of the multiple sensors 2181 to 218q, 2281 to 228s, 2381 to 238u, 2481 to 248w, 2581 to 258y (hereinafter referred to as “sensor group”) via multiple sequencers 219, 229, 239, 249, 259 (hereinafter referred to as “sequencer group”). The control section 260 operates the multiple modules 2171 to 217p, 2271 to 227r, 2371 to 237t, 2471 to 247v, and 2571 to 257x (hereinafter referred to as “module group”) in cooperation to perform a series of substrate processes including loading, polishing, cleaning, drying, film-thickness measuring, and unloading.

### (Hardware Configuration of Each Device)

FIG. 8 is a hardware configuration diagram showing an example of a computer 900. Each of the control unit 26, the database device 3, the machine-learning device 4, the information processing device 5, and the user terminal device 6 of the substrate processing device 2 is configured by the general-purpose or dedicated computer 900.

As shown in FIG. 8, main components of the computer 900 include buses 910, a processor 912, a memory 914, an input device 916, an output device 917, a display device 918, a storage device 920, a communication I/F (interface) section 922, an external device I/F section 924, an I/O (input/output) device I/F section 926, and a media input/output section 928. The above components may be omitted as appropriate depending on an application in which the computer 900 is used.

The processor 912 includes one or more arithmetic processing unit(s) (CPU (Central Processing Unit), MPU (Micro-processing unit), DSP (digital signal processor), GPU (Graphics Processing Unit), etc.), and operates as a controller configured to control the entire computer 900. The memory 914 stores various data and programs 930, and includes, for example, a volatile memory (DRAM, SRAM, etc.) that functions as a main memory, a non-volatile memory (ROM), a flash memory, etc.

The input device 916 includes, for example, a keyboard, a mouse, a numeric keypad, an electronic pen, etc., and functions as an input section. The output device 917 includes, for example, a sound (voice) output device, a vibration device, etc., and functions as an output section. The display device 918 includes, for example, a liquid crystal display, an organic EL display, electronic paper, a projector, etc., and functions as an output section. The input device 916 and the display device 918 may be configured integrally, such as a touch panel display. The storage device 920 includes, for example, HDD (Hard Disk Drive), SSD (Solid State Drive), etc., and functions as a storage section. The storage device 920 stores various data necessary for executing the operating system and the programs 930.

The communication I/F section 922 is coupled to a network 940, such as the Internet or an intranet (which may be the same as the network 7 in FIG. 1), in a wired manner or a wireless manner, and transmits and receives data to and from another computer according to a predetermined communication standard. The communication I/F section 922 functions as a communication unit that sends and receives information. The external device I/F section 924 is coupled to an external device 950, such as camera, printer, scanner, reader/writer, etc. in a wired manner or a wireless manner, and serves as a communication section that transmits and receives data to and from the external device 950 according to a predetermined communication standard. The I/O device I/F unit 926 is coupled to 110 devices 960, such as various sensors or actuators, and functions as a communication unit that transmits and receives various signals, such as detection signals from the sensors or control signals to the actuators, and data to and from the I/O devices 960. The media input/output unit 928 is constituted of a drive device, such as a DVD drive or a CD drive, and writes and reads data into and from medium (non-transitory storage medium) 970, such as a DVD or a CD.

In the computer 900 having the above configurations, the processor 912 calls the program 930 stored in the storage device 920 into the memory 914 and executes the program 930, and controls each part of the computer 900 via the buses 910. The program 930 may be stored in the memory 914 instead of the storage device 920. The program 930 may be stored in the medium 970 in an installable file format or an executable file format, and may be provided to the computer 900 via the media input/output unit 928. The program 930 may be provided to the computer 900 by being downloaded via the network 940 and the communication I/F unit 922. The computer 900 performs various functions realized by the processor 912 executing the programs 930. The computer 900 may include hardware, such an FPGA, an ASIC, etc. for executing the above-described various functions.

The computer 900 is, for example, a stationary computer or a portable computer, and is an electronic device in arbitrary form. The computer 900 may be a client computer, a server computer, or a cloud computer. The computer 900 may be applied to devices other than the devices 2 to 6.

### (Production History Information 30)

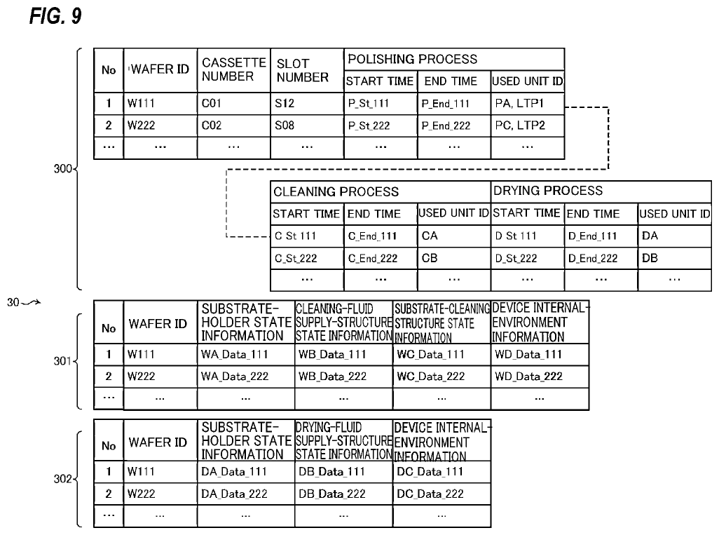

FIG. 9 is a data configuration diagram showing an example of the production history information 30 managed by the database device 3. The production history information 30 includes, for example, a wafer history table 300 with respect to each of the wafers W, a cleaning history table 301 with respect to the device-state information in the cleaning process, and a drying history table 302 with respect to the device-state information in the drying process, as a table in which the reports R obtained in the substrate process of the wafer W for proper production are classified and registered. The production history information 30 includes a polishing history table with respect to the device-state information in the polishing process, an event history table with respect to the event information, a manipulation history table with respect to the manipulation information, and the like, in addition to the above-described tables, but detailed descriptions thereof are omitted.

For example, a wafer ID, a cassette number, a slot number, start time and end time of each process, a used unit ID, etc. are registered in each record of the wafer history table 300. The polishing process, the cleaning process, and the drying process are illustrated as examples in FIG. 9. Data is registered in the other processes in the same manner.

For example, a wafer ID, substrate-holder state information, cleaning-fluid-supply-structure state information, substrate-cleaning-structure state information, and device internal-environment information are registered in each record of the cleaning history table 301.

The substrate-holder state information is information indicating a state of the substrate holder 241 in the cleaning process. The substrate-holder state information is, for example, detection values of each sensor (or command values to each module) sampled at predetermined time intervals by the sensor group (or the module group) of the substrate holder 241.

The cleaning-fluid-supply-structure state information is information indicating a state of the cleaning-fluid supply structure 242 in the cleaning process. The cleaning-fluid-supply-structure state information is, for example, detection values of each sensor (or command values to each module) sampled at predetermined time intervals by the sensor group (or the module group) of the cleaning-fluid supply structure 242.

The substrate-cleaning-structure state information is information indicating a state of the substrate cleaning structure 240 in the cleaning process. The substrate-cleaning-structure state information is, for example, detection values of each sensor (or command values to each module) sampled at predetermined time intervals by the sensor group (or the module group) of the substrate cleaning structure 240.

The device internal-environment information is information indicating a state of the internal space of the substrate processing device 2 formed by the housing 20. The internal space of the substrate processing device 2 is a space in which the roll-sponge cleaning sections 24A, 24B or the pen-sponge cleaning sections 24C, 24D are arranged. The device internal-environment information is, for example, detection values of each sensor sampled by the environmental sensor 244 at predetermined time intervals.

By referring to the cleaning history table 301, time-series data of each sensor (or time-series data of each module) can be extracted as a state of the substrate processing device 2 when the cleaning process is performed on the wafer W identified by the wafer ID.

For example, a wafer ID, substrate-holder state information, drying-fluid-supply-structure state information, and device internal-environment information are registered in each record of the drying history table 302.

The substrate-holder state information is information indicating a state of the substrate holder 241 in the drying process. The substrate-holder state information is, for example, detection values of each sensor (or command values to each module) sampled at predetermined time intervals by the sensor group (or the module group) of the substrate holder 241.

The drying-fluid-supply-structure state information is information indicating a state of the drying-fluid supply structure 245 in the drying process. The drying-fluid-supply-structure state information is, for example, detection values of each sensor (or command values to each module) sampled at predetermined time intervals by the sensor group (or the module group) of the drying-fluid supply structure 245.

The device internal-environment information is information indicating a state of the internal space of the substrate processing device 2 formed by the housing 20. The internal space of the substrate processing device 2 is a space in which the drying sections 24E and 24F are disposed. The device internal-environment information is, for example, detection values of each sensor sampled by the environment sensors 244 at predetermined time intervals.

By referring to the drying history table 302, time-series data of each sensor (or time-series data of each module) can be extracted as a state of the substrate processing device 2 when the drying process is performed on the wafer W identified by the wafer ID.

### (Finishing-Test Information 31)

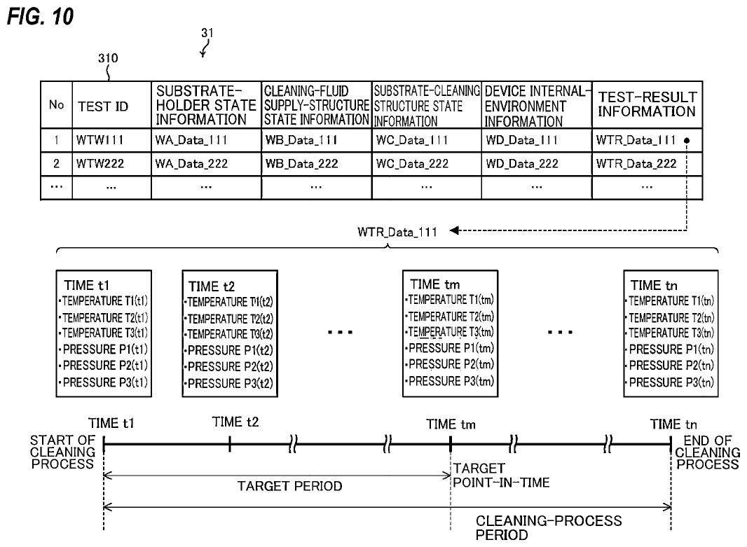

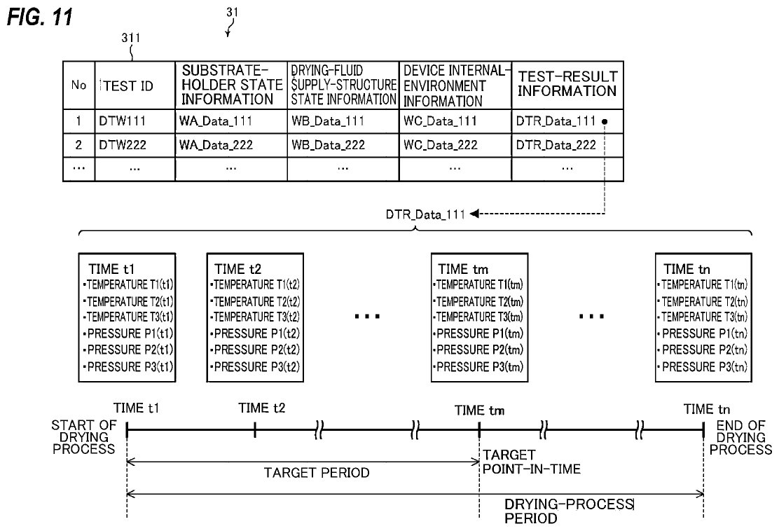

FIG. 10 is a data configuration diagram showing an example of the finishing-test information 31 managed by the database device 3. FIG. 11 is a data structure diagram showing an example of a drying-test table 311 of the finishing-test information 31 managed by the database device 3. The finishing-test information 31 includes a cleaning-test table 310 (FIG. 10) in which the report R and test results obtained in a cleaning test performed using a dummy wafer are classified and registered, and a drying-test table 311 (FIG. 11) in which the report R and test results obtained in a drying test performed using a dummy wafer are classified and registered.

As shown in FIG. 10, a test ID, the substrate-holder state information, the cleaning-fluid-supply-structure state information, the substrate-cleaning-structure state information, the device internal-environment information, the test result information, etc. are registered in each record of the cleaning-test table 310. The substrate-holder state information, the cleaning-fluid-supply-structure state information, the substrate-cleaning-structure state information, and the device internal-environment information of the cleaning-test table 310 are information indicating the state of each unit in the cleaning test. Their data configurations are the same as those of the cleaning history table 301, and therefore detailed explanations will be omitted.

As shown in FIG. 11, a test ID, the substrate-holder state information, the drying-fluid-supply-structure state information, the device internal-environment information, the test result information, etc. are registered in each record of the drying-test table 311. The substrate-holder state information, the drying-fluid-supply-structure state information, and the device internal-environment information of the drying-test table 311 are information indicating the state of each unit in the drying test. Their data configurations are the same as those of the drying history table 302, and therefore detailed explanations will be omitted.

The test result information is information indicating the state of the dummy wafer when the finishing process (i.e., the cleaning process, the drying process) is performed on the dummy wafer in the finishing test (i.e., the cleaning test, the drying test). The test result information is detection values of the dummy-wafer sensor sampled at predetermined time intervals by the dummy-wafer sensor of the dummy wafer. The test result information shown in FIGS. 10 and 11 are obtained by the dummy-wafer sensors including three temperature sensors and three pressure sensors. Therefore, the test result information shown in FIGS. 10 and 11 includes detection values T1 to T3, P1 to P3 at times t1, t2, . . . , . . . tm, . . . , tn within a finish-process period from start to end of the finishing process. The test result information may be the detection values of the dummy-wafer sensors as described above. Alternatively, a camera mounted to an optical microscope or a scanning electron microscope (SEM) may generate images of the dummy wafer at predetermined time intervals, and the test result information may be obtained based on a result of image processing performed on the images, or based on a result of experimental analysis performed on the images by an experimenter. Further, the test result information may be collected in one finishing test which is performed consecutively from start to end of the finishing process, or may be collected in multiple finishing tests which are performed repeatedly from start of the finishing process until a predetermined time is reached, with the predetermined time gradually lengthened.

By referring to the cleaning-test table 310, time-series data of each sensor (or time-series data of each module) indicating a state of the roll-sponge cleaning sections 24A, 24B or the pen-sponge cleaning sections 24C, 24D when the cleaning process is performed on the dummy wafer in the cleaning test identified by the test ID, and time-series data of the dummy-wafer sensor indicating the state of the dummy wafer at that time can be extracted. Furthermore, by referring to the drying-test table 311, time-series data of each sensor (or time-series data of each module) indicating a state of the drying sections 24E, 24F when the drying process is performed on the dummy wafer in the drying test identified by the test ID, and time-series data of the dummy-wafer sensor indicating the state of the dummy wafer at that time can be extracted.

### (Machine-Learning Device 4)

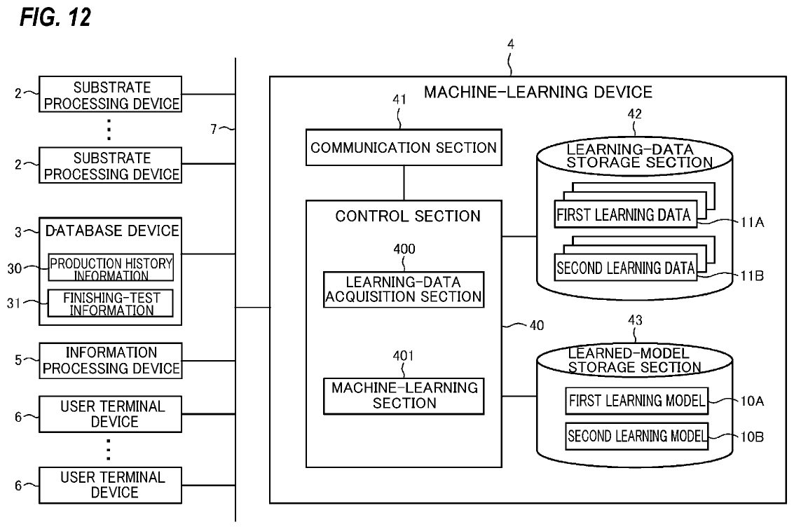

FIG. 12 is a block diagram showing an example of the machine-learning device 4 according to the first embodiment. The machine-learning device 4 includes a control section 40, a communication section 41, a learning-data storage section 42, and a learned-model storage section 43.

The control section 40 functions as a learning-data acquisition section 400 and a machine-learning section 401. The communication section 41 is coupled to external devices (e.g., the substrate processing device 2, the database device 3, the information processing device 5, the user terminal device 6, the cleaning-test device (not shown), the drying-test device (not shown), etc.) via the network 7. The communication section 41 serves as a communication interface configured to transmit and receive various data.

The learning-data acquisition section 400 is coupled to an external device via the communication section 41 and the network 7. The learning-data acquisition section 400 acquires the first learning data 11A including cleaning conditions as input data and the substrate state information as output data, and further acquires the second learning data 11B including drying conditions as input data and the substrate state information as output data. The first and second learning data 11A and 11B are data used as teacher data (or training data), verification data, and test data in supervised learning. The substrate state information is used as ground-truth label or correct label in the supervised learning.

The learning-data storage section 42 is a database that stores multiple sets of the first and second learning data 11A, 11B acquired by the learning-data acquisition section 400. The specific configuration of the database constituting the learning-data storage section 42 may be designed as appropriate.

The machine-learning section 401 performs the machine learning using the multiple sets of first and second learning data 11A, 11B stored in the learning-data storage section 42. Specifically, the machine-learning section 401 inputs the multiple sets of first learning data 11A to the first learning model 10A and causes the first learning model 10A to learn a correlation between the cleaning conditions and the substrate state information included in the first learning data 11A to thereby create the first learning model 10A as a learned model. Further, the machine-learning section 401 inputs the multiple sets of second learning data 11B to the second learning model 10B and causes the second learning model 10B to learn a correlation between the drying conditions and the substrate state information included in the second learning data 11B to thereby create the second learning model 10B as a learned model.

The learned-model storage section 43 is a database configured to store the first learning model 10A as the learned model (i.e., adjusted weight parameter group) created by the machine-learning section 401. The first and second learning models 10A and 10B as the learned models stored in the learned-model storage section 43 are provided to a real system (e.g., the information processing device 5) via the network 7, a storage medium, or the like. Although the learning-data storage section 42 and the learned-model storage section 43 are shown as separate storage sections in FIG. 12, they may be configured as a single storage section.

The number of first and second learning models 10A and 10B stored in the learned-model storage section 43 is not limited to one. For example, a plurality of learning models may be stored in the learned-model storage section 43 for different conditions, such as a machine learning method, a type of wafer W (size, thickness, film type, etc.), a type of cleaning tool, a difference in mechanism of the substrate cleaning device (the substrate holder 241, the cleaning-fluid supply structure 242, the substrate cleaning structure 240, and the cleaning-tool cleaning structure 243), a difference in mechanism of the substrate drying device (the substrate holder 241 and the drying-fluid supply structure 245), a type of substrate cleaning fluid and a type of substrate drying fluid, types of data included in the cleaning conditions and the drying conditions, types of data included in the substrate state information, etc. In that case, a plurality of types of learning data having data configurations corresponding respectively to the plurality of learning models for the different conditions may be stored in the learning-data storage section 42.

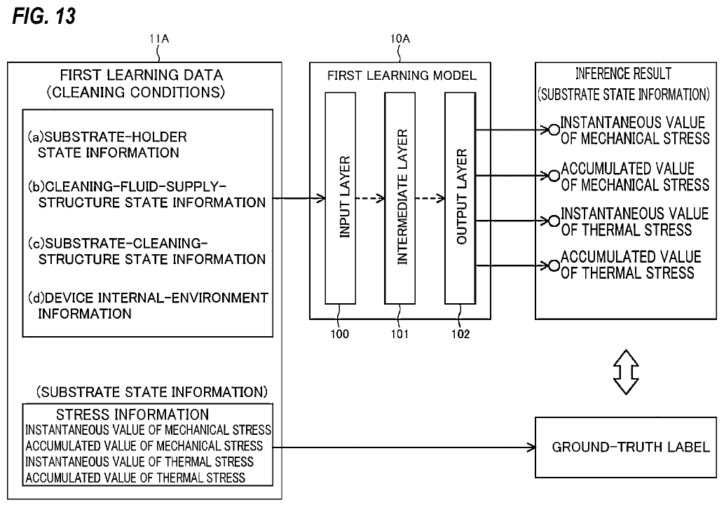

FIG. 13 is a diagram showing an example of the first learning model 10A and the first learning data 11A. The first learning data 11A used for the machine learning of the first learning model 10A is composed of the clearing conditions and the substrate state information. In this embodiment, the first learning model 10A and the first learning data 11A are prepared for at least two types corresponding to the roll sponge cleaning sections 24A and 24B using the roll sponges 2400 and the pen sponge cleaning sections 24C and 24D using the pen sponge 2401. Since the basic data structure is common, they will be explained together below.

The cleaning conditions constituting the first learning data 11A include the substrate-holder state information indicating the state of the substrate holder 241 in the cleaning process of the wafer W performed by the substrate processing device 2, the cleaning-fluid-supply-structure state information indicating the state of the cleaning-fluid supply structure 242, and the substrate-cleaning-structure state information indicating the state of the substrate cleaning structure 240. The cleaning-fluid-supply-structure state information corresponds to the finishing-fluid-supply-structure state information.

The substrate-holder state information included in the cleaning conditions includes at least one of the number of holding points at which the substrate holding mechanism 241a, 241c holds the substrate, the holding pressure at which the substrate holding mechanism 241a, 241c holds the substrate, the rotation speed of the substrate holding mechanism 241a, 241c, the rotation torque of the substrate rotating mechanism 241b, 241d, and the condition of the substrate holding mechanism 241a, 241c. The condition of the substrate holding mechanism 241a, 241c represents a degree of wear and a degree of dirt of the substrate holding mechanism 241a, 241c, which is set based on a use condition of the substrate holding mechanism 241a, 241c (use time, pressure during use, replaced or not replaced, the rotation speed of the wafer W, and the number of wafers processed). The condition of the substrate holding mechanism 241a, 241c may change over time during the cleaning process, for example.

The cleaning-fluid-supply-structure state information included in the cleaning conditions includes at least one of flow rate of the substrate cleaning fluid, pressure of the substrate cleaning fluid, dropping position of the substrate cleaning fluid, temperature of the substrate cleaning fluid, and concentration of the substrate cleaning fluid. The substrate cleaning fluid is an example of a substrate finishing fluid. In the case where the substrate cleaning fluid is a plurality of types of fluid, the cleaning-fluid-supply-structure state information may include flow rate, pressure, dropping position, temperature, and concentration of each fluid.

The substrate-cleaning-structure state information included in the cleaning conditions includes at least one of the rotation speed of the cleaning-tool rotating mechanism 240a, the rotation torque of the cleaning-tool rotating mechanism 240a, the position coordinates of the cleaning-tool moving mechanism (the vertical movement mechanism 240b, 240e, the linear movement mechanism 240c, the swing movement mechanism 240f), the movement speed of the cleaning-tool moving mechanism, the movement torque of the cleaning-tool moving mechanism, the pressing load at which the cleaning tool is brought into contact with the wafer W, and the condition of the cleaning tool. The condition of the cleaning tool indicates a degree of wear or a degree of dirt of the cleaning tool, which is set based on, for example, a use condition of the cleaning tool (use time, pressing load during use, replaced or not replaced, an image of the surface of the cleaning tool, the rotation speed of the cleaning tool, the rotation speed of the wafer W, and the number of wafers processed). The condition of the cleaning tool may change over time during the cleaning process, for example.

The cleaning conditions may further include device internal-environment information indicating an environment of a space in which the cleaning process is performed. The device internal-environment information included in the cleaning conditions includes at least one of temperature, humidity, atmospheric pressure, air flow, oxygen concentration, and sound of the internal space formed by the housing 20.

The substrate state information constituting the first learning data 11A is information indicating the state of the wafer W that has been subjected to the cleaning process under the cleaning conditions. In this embodiment, the substrate state information is stress information indicating at least one of mechanical stress and thermal stress applied to the wafer W. The stress information may indicate, for example, an instantaneous value of stress at a target point in time included in a cleaning-process period from the start to the end of the cleaning process (a time required for the cleaning process per wafer), or an accumulated value of stress during a target period from the start of the cleaning process to the target point in time (i.e., an arbitrary period equal to or less than the clearing-process period), or may indicate a surface distribution state of the stress applied to the substrate surface of the wafer W.

The learning-data acquisition section 400 acquires the first learning data 11A by referring to the finishing-test information 31 and receiving, as necessary, the input manipulations of the user through the user terminal device 6. For example, the learning-data acquisition section 400 refers to the cleaning-test table 310 of the finishing-test information 31, thereby acquiring the cleaning conditions including the substrate-holder state information, the cleaning-fluid-supply-structure state information, and the substrate-cleaning-structure state information (time-series data of sensors of the substrate holder 241, the cleaning-fluid supply structure 242, and the substrate cleaning structure 240) when the cleaning test identified by the test ID is performed.

The learning-data acquisition section 400 refers to the cleaning-test table 310 of the finishing-test information 31, thereby acquiring, as the substrate state information corresponding to the cleaning conditions, the test-result information (e.g., the time-series data (see FIG. 10) of the dummy-wafer sensor of the dummy wafer) when the cleaning test identified by the same test ID is performed. At that time, each time-series data of the pressure sensor corresponds to the instantaneous value of the mechanical stress, and each time-series data of the temperature sensor corresponds to the instantaneous value of the thermal stress. When a plurality of dummy-wafer sensors are dispersedly arranged on the substrate surface of the dummy wafer, or are configured to be able to planarly measure, the learning-data acquisition section 400 acquires measurement values at a plurality of measuring points or an in-plane measurement value as the instantaneous value at the target point-in-time. Further, the learning-data acquisition section 400 acquires the accumulated value of the mechanical stress in the target period by accumulating the time-series data of pressure data included in the target period, and the learning-data acquisition section 400 acquires the accumulated value of the thermal stress in the target period by accumulating the time-series data of temperature data included in the target period.

The first learning model 10A employs, for example, a neural network structure, and includes an input layer 100, an intermediate layer 101, and an output layer 102. Synapses (not shown) connecting neurons are placed between the layers, and each synapse is associated with a weight. A weight parameter group including weights of the synapses is adjusted by the machine learning.

The input layer 100 has neurons corresponding to the cleaning conditions as the input data, and each value of the cleaning conditions is input to each neuron. The output layer 102 has neuron(s) corresponding to the substrate state information as the output data, and a prediction result (inference result) of the substrate state information for the cleaning conditions is output as the output data. When the first learning model 10A is constituted of a regression model, the substrate state information is output as a numerical value normalized to a predetermined range (e.g., 0 to 1). When the first learning model 10A is constituted of a classification model, the substrate state information is output as a numerical value normalized to a predetermined range (e.g., 0 to 1) as a score (confidence) for each class.

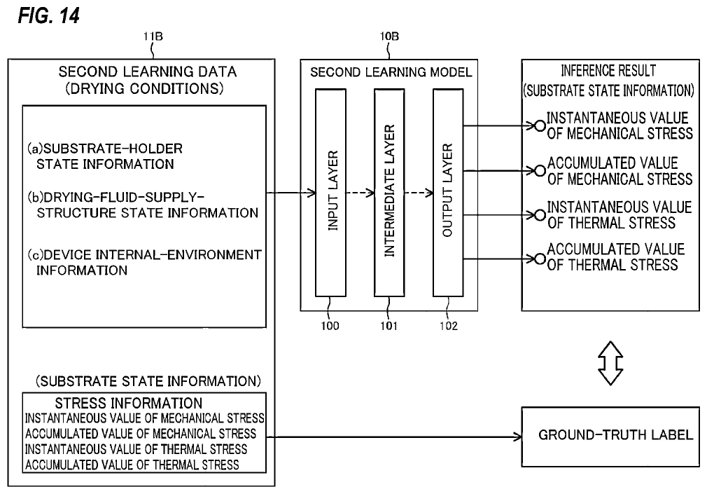

FIG. 14 is a diagram showing an example of the second learning model 10B and the second learning data 11B. The second learning data 11B used for the machine learning of the second learning model 10B is composed of the drying conditions and the substrate state information.

The drying conditions constituting the second learning data 11B include substrate-holder state information indicating the state of the substrate holder 241 in the drying process of the wafer W performed by the substrate processing device 2, and drying-fluid-supply-structure state information indicating the state of the drying-fluid supply structure 245. The drying-fluid-supply-structure state information corresponds to the finishing-fluid-supply-structure state information. The substrate-holder state information is similar to the first learning data 11A, and therefore a description thereof will be omitted.

The drying-fluid-supply-structure state information included in the drying conditions includes at least one of flow rate of the substrate drying fluid, pressure of the substrate drying fluid, dropping position of the substrate drying fluid, temperature of the substrate drying fluid, and concentration of the substrate drying fluid. The substrate drying fluid is an example of the substrate finishing fluid. In the case where the substrate drying fluid is a plurality of types of fluid, the drying-fluid-supply-structure state information may include flow rate, pressure, dropping position, temperature, and concentration of each fluid.

The drying conditions may further include device internal-environment information indicating an environment of a space in which the drying process is performed. The device internal-environment information included in the drying conditions includes at least one of temperature, humidity, atmospheric pressure, air flow, oxygen concentration, and sound of the internal space formed by the housing 20.

The substrate state information constituting the second learning data 11B is information indicating the state of the wafer W that has been subjected to the drying process under the drying conditions. In this embodiment, the substrate state information is stress information indicating at least one of mechanical stress and thermal stress applied to the wafer W. The stress information may indicate, for example, an instantaneous value of stress at a target point in time included in a drying-process period from the start to the end of the drying process (a time required for the drying process per wafer), or an accumulated value of stress during a target period from the start of the drying process to the target point in time (i.e., an arbitrary period equal to or less than the drying-process period), or may indicate a surface distribution state of the stress applied to the substrate surface of the wafer W.

The learning-data acquisition section 400 acquires the second learning data 11B by referring to the finishing-test information 31 and receiving, as necessary, the input manipulations of the user through the user terminal device 6. For example, the learning-data acquisition section 400 refers to the drying-test table 311 of the finishing-test information 31, thereby acquiring the drying conditions including substrate-holder state information and drying-fluid-supply-structure state information (time-series data of sensors of the substrate holder 241 and the drying-fluid supply structure 245) when the drying test identified by the test ID is performed.

The learning-data acquisition section 400 refers to the drying-test table 311 of the finishing-test information 31, thereby acquiring, as the substrate state information corresponding to the drying conditions, the test-result information (e.g., the time-series data (see FIG. 11) of the dummy-wafer sensor of the dummy wafer) when the drying test identified by the same test ID is performed. At that time, each time-series data of the pressure sensor corresponds to the instantaneous value of the mechanical stress, and each time-series data of the temperature sensor corresponds to the instantaneous value of the thermal stress. When a plurality of dummy-wafer sensors are dispersedly arranged on the substrate surface of the dummy wafer, or are configured to be able to planarly measure, the learning-data acquisition section 400 acquires measurement values at a plurality of measuring points or an in-plane measurement value as the instantaneous value at the target point-in-time. Further, the learning-data acquisition section 400 acquires the accumulated value of the mechanical stress in the target period by accumulating the time-series data of pressure data included in the target period, and the learning-data acquisition section 400 acquires the accumulated value of the thermal stress in the target period by accumulating the time-series data of temperature data included in the target period.

The second learning model 10B employs, for example, a neural network structure, and includes an input layer 100, an intermediate layer 101, and an output layer 102. Synapses (not shown) connecting neurons are placed between the layers, and each synapse is associated with a weight. A weight parameter group including weights of the synapses is adjusted by the machine learning.

The input layer 100 has neurons corresponding to the drying conditions as the input data, and each value of the drying conditions is input to each neuron. The output layer 102 has neuron(s) corresponding to the substrate state information as the output data, and a prediction result (inference result) of the substrate state information for the drying conditions is output as the output data. When the second learning model 10B is constituted of a regression model, the substrate state information is output as a numerical value normalized to a predetermined range (e.g., 0 to 1). When the second learning model 10B is constituted of a classification model, the substrate state information is output as a numerical value normalized to a predetermined range (e.g., 0 to 1) as a score (confidence) for each class.

In this embodiment, a case will be described where the finishing conditions (the cleaning conditions, the drying conditions) are acquired as the time-series data of the sensor group as shown in FIGS. 13 and 14. The finishing conditions may be changed as appropriate according to constructions of the finishing unit 24 (the substrate cleaning device, the substrate drying device). In addition, a command value to the module, a parameter converted from a detected value of the sensor or the command value to the module, or a parameter calculated based on detected values of a plurality of sensors may be used as the cleaning conditions and the drying conditions. Furthermore, the finishing conditions may be acquired as time-series data in the entire finishing-process period (the cleaning-process period, the drying-process period), may be acquired as time-series data in a target period that is part of the finishing-process period, or may be acquired as point-in-time data at a specific target point-in-time. When the definition of the finishing-process period is changed as described above, the data structure of the input data in the first and second learning models 10A and 10B and the first and second learning data 11A and 11B may be changed as appropriate.

In this embodiment, a case will be described where the substrate state information is the instantaneous value and the accumulated value of the mechanical stress and the instantaneous value and the accumulated value of the thermal stress as shown in FIGS. 13 and 14, but the substrate state information may include at least one of these values. The mechanical stress and the thermal stress may be calculated by substituting the measurement value of the dummy-wafer sensor into a predetermined calculation formula. Further, when the finishing conditions are acquired as the time-series data in the entire finishing-process period or the time-series data in the target period that is part of the finishing-process period, the substrate state information may be acquired as time-series data in the entire finishing-process period or time-series data in the target period, or may be acquired as point-in-time data at the end of finishing process of the wafer W or point-in-time data at the target point-in-time. When the finishing conditions are acquired as, for example, the point-in-time data at the specific target point-in-time, the substrate state information may be acquired as point-in-time data at the specific target point-in-time. When the definition of the substrate state information is changed as described above, the data structure of the output data in the first and second learning models 10A and 10B and the first and second learning data 11A and 11B may be changed as appropriate.

### (Machine Learning Method)

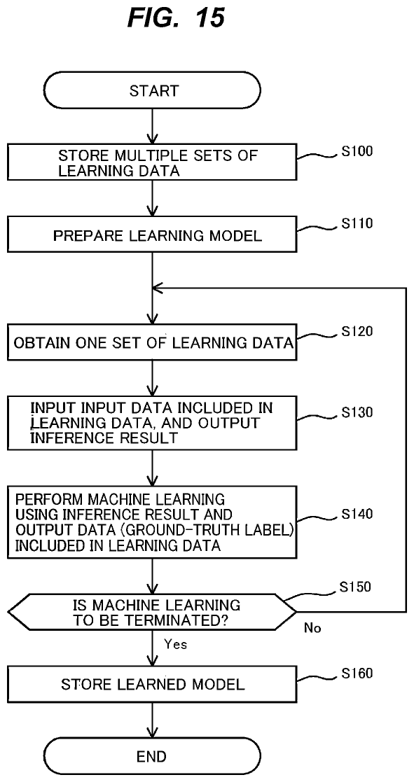

FIG. 15 is a flowchart showing an example of a machine learning method performed by the machine-learning device 4. Below, a case where the first learning model 10A (referred to as learning model in FIG. 15) is generated using multiple sets of first learning data 11A (referred to as learning data in FIG. 15) is described. The same applies to a case where the second learning model 10B is created using the second learning data 11B, and descriptions thereof will be omitted.

First, in step S100, the learning-data acquisition section 400 obtains, from the finishing-test information 31 or the like, a desired number of first learning data 11A as advance preparation for starting the machine learning, and stores the obtained first learning data 11A in the learning-data storage section 42. The number of first learning data 11A to be prepared may be set in consideration of the inference accuracy required for the first learning model 10A finally obtained.

Next, in step S110, the machine-learning section 401 prepares the first learning model 10A before learning for starting the machine learning. The first learning model 10A prepared before learning in this embodiment is composed of the neural network model as shown in FIG. 13, and the weight of each synapse is set to an initial value.

Next, in step S120, the machine-learning section 401 randomly obtains, for example, one set of first learning data 11A from the multiple sets of first learning data 11A stored in the learning-data storage section 42.

Next, in step S130, the machine-learning section 401 inputs the cleaning conditions (input data) included in the one set of first learning data 11A to the input layer 100 of the prepared first learning model 10A before learning (or during learning). As a result, the substrate state information (the output data) is output as the inference result from the output layer 102 of the first learning model 10A. However, the output data is generated by the first learning model 10A before learning (or during learning). Therefore, in the state before learning (or during learning), the output data output as the inference result may indicate different information from the substrate state information (ground-truth label or correct label) included in the first learning data 11A.

Next, in step S140, the machine-learning section 401 performs the machine learning by comparing the substrate state information (ground-truth label or correct label) included in the one set of first learning data 11A acquired in the step S120 with the substrate state information (output data) output as the inference result from the output layer in the step S130, and adjusting the weight of each synapse (backpropagation). In this way, the machine-learning section 401 causes the first learning model 10A to learn a correlation between the cleaning conditions and the substrate state information.

Next, in step S150, the machine-learning section 401 determines whether a predetermined learning end condition is satisfied. For example, this determination is made based on an evaluation value of an error function based on the substrate state information (ground-truth label or correct label) included in the first learning data 11A and the substrate state information (output data) output as the inference result, or the remaining number of unlearned first learning data 11A stored in the learning-data storage section 42.

In the step S150, if the machine-learning section 401 has determined that the learning end condition is not satisfied and the machine learning is to be continued (“No” in the step S150), the process returns to the step S120, and the steps S120 to S140 are performed on the first learning model 10A multiple times using the unlearned first learning data 11A. On the other hand, if the machine-learning section 401 has determined that the learning end condition is satisfied and the machine learning is to be terminated (“Yes” in the step S150) in the step S150, the process proceeds to step S160.

Then, in the step S160, the machine-learning section 401 stores, in the learned-model storage section 43, the first learning model 10A as the learned model (adjusted weight parameter group) created by adjusting the weight associated with each synapse. The sequence of machine-learning processes shown in FIG. 15 is completed. In the machine-learning method, the step S100 corresponds to a learning-data storing process, the steps S110 to S150 correspond to a machine-learning process, and the step S160 corresponds to a learned-model storing process.

As described above, the machine-learning device 4 and the machine learning method according to the present embodiment can provide the first learning model 10A capable of predicting (inferring) the substrate state information indicating the state of the wafer W from the cleaning conditions including the substrate-holder state information, the cleaning-fluid-supply-structure state information, and the substrate-cleaning-structure state information, etc. The machine-learning device 4 and the machine learning method according to the present embodiment can further provide the second learning model 10B that can predict (infer) the substrate state information indicating the state of the wafer W from the drying conditions including the substrate-holder state information, the drying-fluid supply-structure state information, etc.

### (Information Processing Device 5)

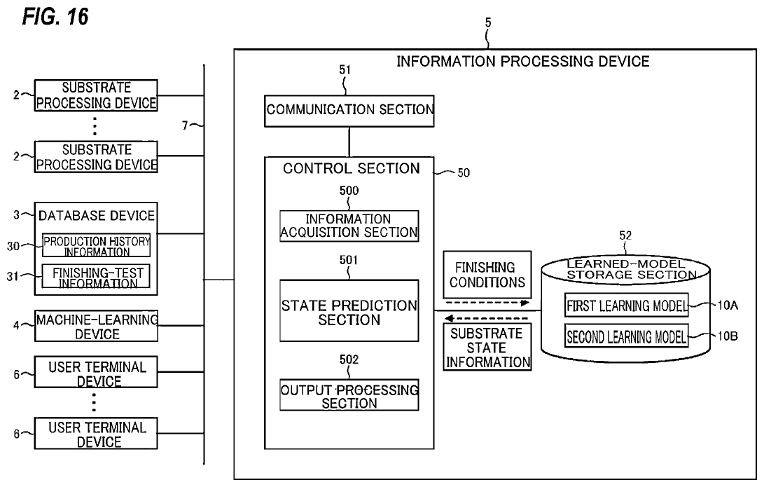

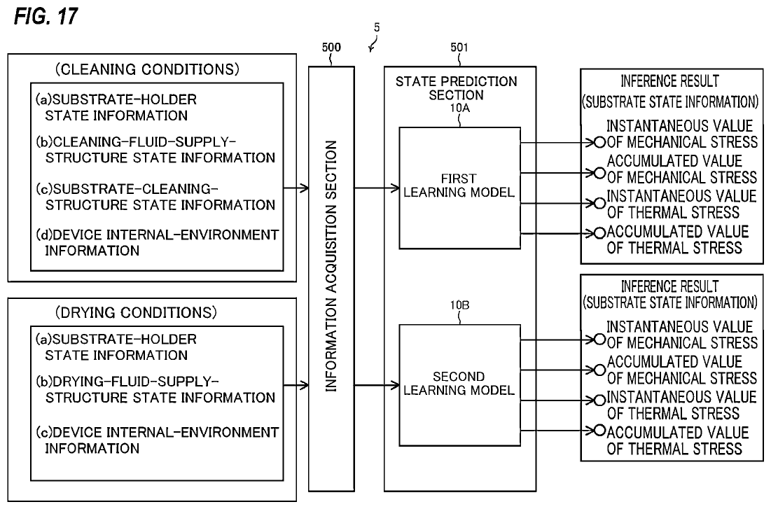

FIG. 16 is a block diagram showing an example of the information processing apparatus 5 according to the first embodiment. FIG. 17 is a functional explanatory diagram showing an example of the information processing apparatus 5 according to the first embodiment. The information processing device 5 includes a control section 50, a communication section 51, and a learned-model storage section 52.

The control section 50 functions as an information acquisition section 500, a state prediction section 501, and an output processing section 502. The communication section 51 is coupled to the external devices (e.g., the substrate processing device 2, the database device 3, the machine-learning device 4, the user terminal device 6, etc.) via the network 7, and serves as a communication interface configured to transmit and receive various data.

The information acquisition section 500 is coupled to an external device via the communication section 51 and the network 7 and acquires the finishing conditions. In this embodiment, the information acquiring section 500 acquires the finishing conditions including the cleaning conditions and the drying conditions. The cleaning conditions include the substrate-holder state information, the cleaning-fluid-supply-structure state information, and the substrate-cleaning-structure state information. The drying conditions include the substrate-holder state information and the drying-fluid-supply-structure state information.

For example, when the “post-predicting process” of the substrate state information is performed for the wafer W on which the cleaning process has already been performed, the information acquisition section 500 refers to the cleaning history table 301 of the production history information 30, thereby acquiring the cleaning conditions including the substrate-holder state information, the cleaning-fluid-supply-structure state information, and the substrate-cleaning-structure state information when the cleaning process is performed on the wafer W. When the “real-time-predicting process” of the substrate state information is performed for the wafer W during the cleaning process, the information acquisition section 500 receives the report R on the device-state information from the substrate processing device 2 performing the cleaning process, thereby acquiring the cleaning conditions including the substrate-holder state information, the cleaning-fluid-supply-structure state information, and the substrate-cleaning-structure state information during the cleaning process of the wafer W. When the “pre-predicting process” of the substrate state information is performed for the wafer W before the cleaning process, the information acquisition section 500 receives the substrate recipe information 266 from the substrate processing device 2 that is to perform the cleaning process of the wafer W and simulates the device-state information when the substrate processing device 2 operates according to the substrate recipe conditions 266, thereby acquiring the cleaning conditions including the substrate-holder state information, the cleaning-fluid-supply-structure state information, and the substrate-cleaning-structure state information when the cleaning process is to be performed on the wafer W.

Furthermore, when the “post-predicting process” of the substrate state information is performed for the wafer W on which the drying process has already been performed, the information acquisition section 500 refers to the drying history table 302 of the production history information 30, thereby acquiring the drying conditions including the substrate-holder state information and the drying-fluid-supply-structure state information when the drying process is performed on the wafer W. When the “real-time-predicting process” of the substrate state information is performed for the wafer W during the drying process, the information acquisition section 500 receives the report R on the device-state information from the substrate processing device 2 performing the drying process, thereby acquiring the drying conditions including the substrate-holder state information and the drying-fluid-supply-structure state information during the drying process of the wafer W. When the “pre-predicting process” of the substrate state information is performed for the wafer W before the drying process, the information acquisition section 500 receives the substrate recipe information 266 from the substrate processing device 2 that is to perform the drying process of the wafer W and simulates the device-state information when the substrate processing device 2 operates according to the substrate recipe conditions 266, thereby acquiring the drying conditions including the substrate-holder state information and the drying-fluid-supply-structure state information when the drying process is to be performed on the wafer W.

As described above, the state prediction section 501 inputs the cleaning conditions as input data acquired by the information acquisition section 500 into the first learning model 10A, thereby predicting the substrate state information (the stress information in this embodiment) for the wafer W that has been subjected to the cleaning processing under the cleaning conditions. Furthermore, as described above, the state prediction section 501 inputs the drying conditions as input data acquired by the information acquisition section 500 into the second learning model 10B, thereby predicting the substrate state information (the stress information in this embodiment) for the wafer W that has been subjected to the drying process under the drying conditions.

The learned-model storage section 52 is a database configured to store the first and second learning models 10A and 10B as the learned models used in the state prediction section 501. The number of first and second learning models 10A and 10B stored in the learned-model storage section 52 is not limited to one. For example, a plurality of learned models may be stored in the learned-model storage section 52 for different conditions, such as machine learning methods, types of wafers W (size, thickness, film type, etc.), types of cleaning tools, a difference in mechanism of substrate cleaning devices, a difference in mechanism of substrate drying devices, types of substrate cleaning fluids and substrate drying fluids, types of data included in the cleaning conditions and the drying conditions, types of data included in the substrate state information, etc. The plurality of learned models may be selectively used. In this embodiment, the learned-model storage section 52 stores at least two types of first learning models 10A, one corresponding to the roll-sponge cleaning section 24A, 24B using the roll sponges 2400 and the other corresponding to the pen-sponge cleaning section 24C, 24D using the pen sponge 2401. The learned-model storage section 52 further stores the second trained model 10B corresponding to the first and second drying sections 24E and 24F. The learned-model storage section 52 may be a storage section of an external computer (e.g., a server type computer or a cloud type computer). In that case, the state prediction section 501 accesses the external computer.

The output processing section 502 performs output processing to output the substrate state information generated by the state prediction section 501. For example, the output processing section 502 may transmit the substrate state information to the user terminal device 6, so that a display screen based on the substrate state information may be displayed on the user terminal device 6. The output processing section 502 may transmit the substrate state information to the database device 3, so that the substrate state information may be registered in the production history information 30.

### (Information Processing Method)

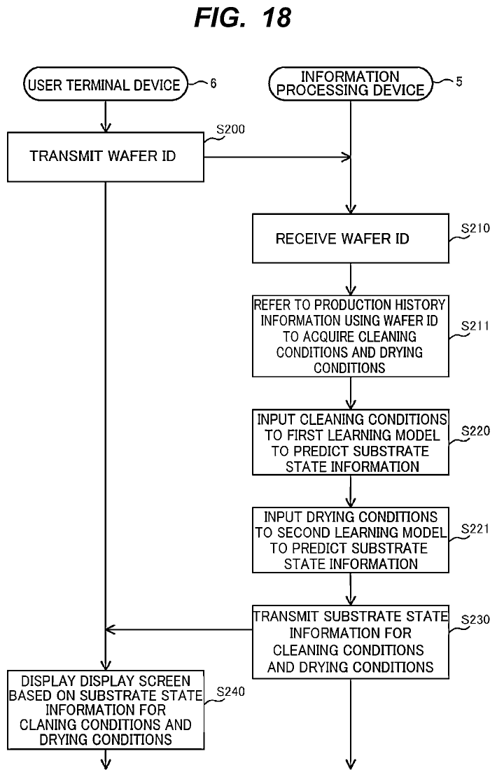

FIG. 18 is a flowchart illustrating an example of an information processing method performed by the information processing device 5. In this embodiment, an operation example will be described in a case where the user manipulates the user terminal device 6 to perform the “post-predicting process” of the substrate state information for a specific wafer W.

First, in step S200, when the user performs an input operation of inputting a wafer ID for identifying a wafer W to be predicted on the user terminal device 6, the user terminal device 6 transmits the wafer ID to the information processing device 5.

Next, in step S210, the information acquisition section 500 of the information processing device 5 receives the wafer ID transmitted in the step S200. In step S211, the information acquisition section 500 uses the wafer ID received in the step S210 to refer to the cleaning history table 301 and the drying history table 302 of the production history information 30, thereby acquiring the cleaning conditions and the drying conditions under which the cleaning process and the drying process are performed on the wafer W identified by the wafer ID.

Next, in step S220, the state prediction section 501 inputs the cleaning conditions acquired in the step S211 as input data into the first learning model 10A, thereby generating the substrate state information for the cleaning conditions as output data, and predicts the state of the wafer W.

Next, in step S221, the state prediction section 501 inputs the drying conditions acquired in the step S211 as input data into the second learning model 10B, thereby generating the substrate state information for the drying conditions as output data and predicting the state of the wafer W.

Next, in step S230, the output processing section 502 transmits the substrate state information corresponding to the cleaning process and the drying process generated in the steps S220 and S211, respectively, to the user terminal device 6 as an output process for outputting the substrate state information. The substrate state information may be transmitted to the database device 3 in addition to or instead of the user terminal device 6.

Next, in step S240, upon receiving the substrate state information transmitted in the step S230, the user terminal device 6 displays a display screen based on the substrate state information corresponding to the cleaning process and the drying process as a response to the transmission process in the step S200. As a result, the state of the wafer W can be visually recognized by the user. In the above information processing method, the steps S210 and S211 correspond to an information acquisition process, the step S220 and S221 corresponds to a state prediction process, and the step S230 corresponds to an output processing process.

As described above, the information processing device 5 and the information processing method according to the present embodiment input the cleaning conditions including the substrate-holder state information, the cleaning-fluid-supply-structure state information, and the substrate-cleaning-structure state information in the cleaning process to the first learning model 10A, and predict the substrate state information (stress information) for the cleaning conditions, so that the state of the wafer W during or after the cleaning process can be appropriately predicted. Furthermore, the information processing device 5 and the information processing method according to the present embodiment input the drying conditions including the substrate-holder state information and the drying-fluid-supply-structure state information in the drying process to the second learning model 10B, and predict the substrate state information (stress information) for the drying conditions, so that the state of the wafer W during or after the drying process can be appropriately predicted.

### Second Embodiment

A second embodiment differs from the first embodiment in that the substrate state information indicating the state of the wafer W on which the finishing process is performed is finishing quality information indicating a finishing quality of the wafer W. In this embodiment, a machine-learning device 4a and an information processing device 5a according to the second embodiment will be described, focusing on differences from the first embodiment.

The finishing quality information may be substrate defect information on a degree of defect and presence or absence of defect of the wafer W, such as cleaning degree information on a degree of cleaning in the cleaning process, drying degree information on a degree of drying in the drying process, scratches, corrosion, etc. The cleaning degree information or the drying degree information may be information on particles, and may include, for example, a surface distribution state of particles or the total number of particles.

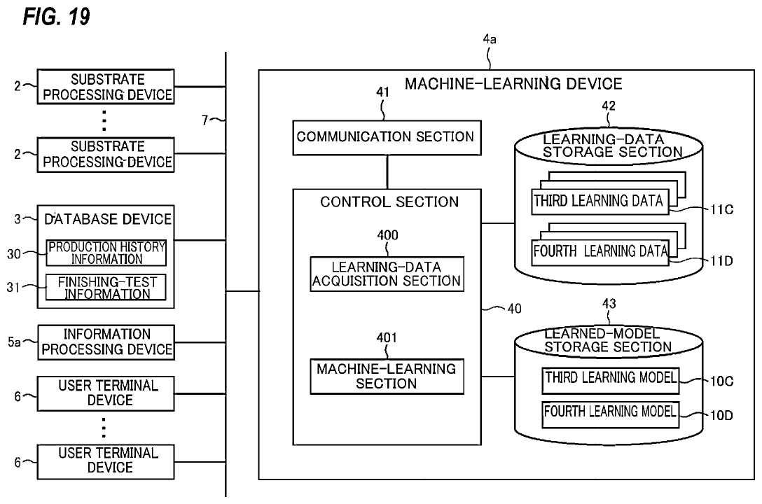

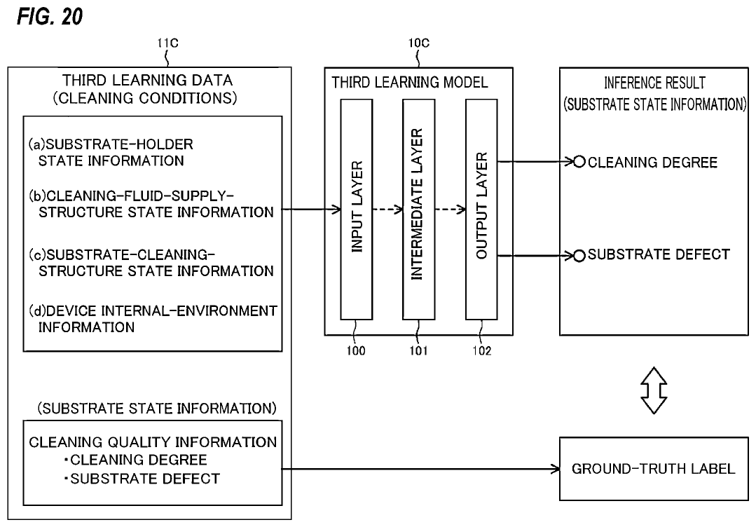

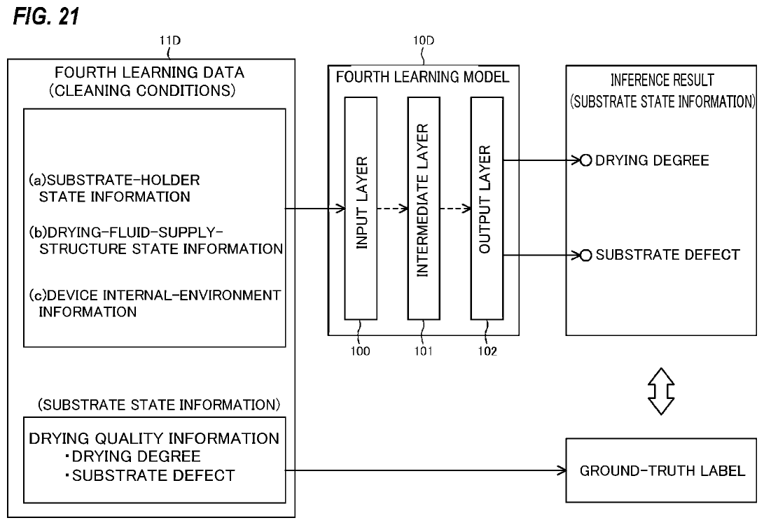

FIG. 19 is a block diagram showing an example of the machine-learning device 4a according to the second embodiment. FIG. 20 is a diagram showing an example of a third learning model 10C and third learning data 11C. FIG. 21 is a diagram showing an example of a fourth learning model 10D and fourth learning data 11D. The third and fourth learning data 11C and 11D are used for machine learning of the third and fourth learning models 10C and 10D, respectively.

The substrate state information constituting the third learning data 11C is, as the finishing quality of the wafer W, the cleaning quality information indicating the cleaning quality of the wafer W in the cleaning process. In this embodiment, a case will be described where the cleaning quality information is the cleaning degree information and the substrate defect information, but the cleaning quality information may include at least one of these information, or may include other information indicating the cleaning quality. The cleaning quality information may indicate the cleaning quality at a target point-in-time in the cleaning-process period from start to end of the cleaning process (i.e., time required for cleaning per wafer), or may indicate an in-plane distribution state of the cleaning quality on the substrate surface of the wafer W. The cleaning conditions constituting the third learning data 11C are the same as those in the first embodiment, and descriptions will be omitted.

The substrate state information constituting the fourth learning data 11CD is, as the finishing quality of the wafer W, the drying quality information indicating the drying quality of the wafer W in the drying process. In this embodiment, a case will be described where the drying quality information is the drying degree information and the substrate defect information, but the drying quality information may include at least one of these information, or may include other information indicating the drying quality. The drying quality information may indicate the drying quality at a target point-in-time in the drying-process period from start to end of the drying process (i.e., time required for drying per wafer), or may indicate an in-plane distribution state of the drying quality on the substrate surface of the wafer W. The drying conditions constituting the fourth learning data 11D are the same as those in the first embodiment, and descriptions will be omitted.

The learning-data acquisition section 400 acquires the third and fourth learning data 11C and 11D by referring to the finishing-test information 31 and receiving, as necessary, the input manipulations of the user through the user terminal device 6. Specifically, the learning-data acquisition section 400 acquires the finishing quality information (the cleaning quality information, the drying quality information) by acquiring the test-result information (e.g., the time-series data of the pressure sensor of the dummy wafer, and the time-series data of the temperature sensor of the dummy wafer) when the finishing test (the cleaning test, the drying test) identified by the test ID from the cleaning-test table 310 and the drying-test table 311 of the finishing-test information 31 is performed, and calculating the finishing quality (the cleaning quality, the drying quality) for each target point-in-time based on, for example, the time-series data of the pressure sensor (mainly reflecting mechanical effects) and the time-series data of the temperature sensor (mainly reflecting chemical effects). The finishing quality information measured by a measuring device, such as an optical microscope or a scanning electron microscope (SEM), may be registered as the test-result information for each target point-in-time in the finishing-test information 31, and in that case, the learning-data acquisition section 400 may further acquire a measurement result of the measuring device as the finishing quality information.

The machine learning section 401 inputs multiple sets of third learning data 11C to the third learning model 10C, and causes the third learning model 10C to learn a correlation between the finishing conditions and the cleaning quality information included in the third learning data 11C, thereby generating the third learning model 10C as a learned model. The machine learning section 401 further inputs multiple sets of fourth learning data 11D to the fourth learning model 10D, and causes the fourth learning model 10D to learn a correlation between the drying conditions and the drying quality information included in the fourth learning data 11D, thereby generating the fourth learning model 10D as a learned model.

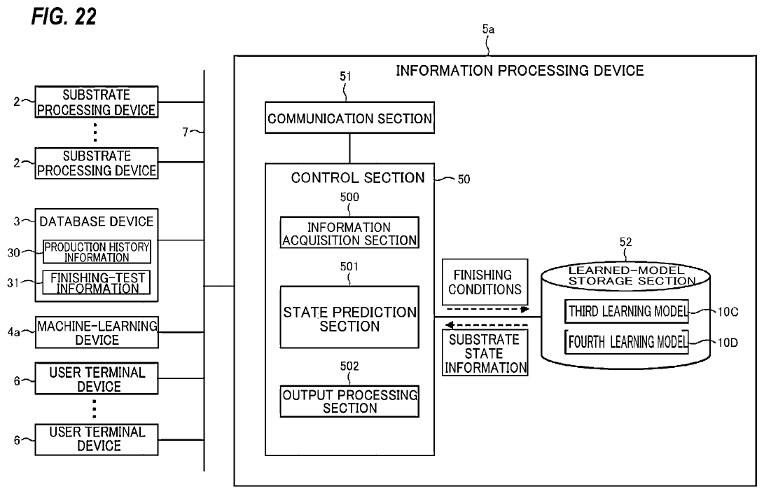

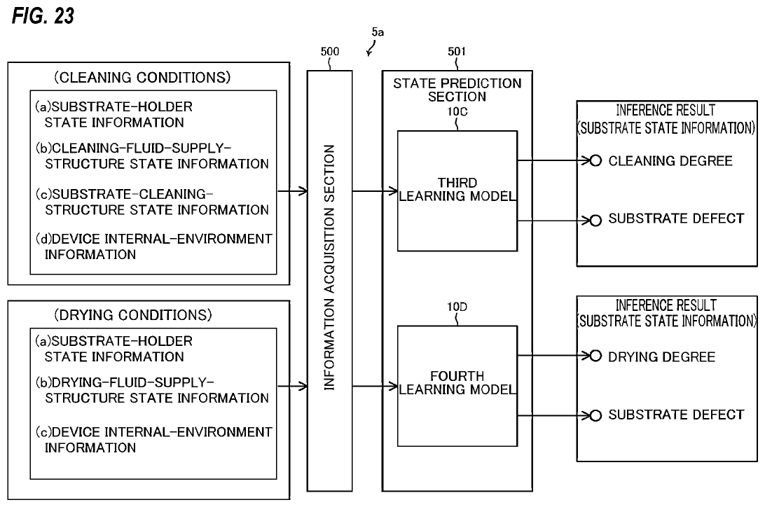

FIG. 22 is a block diagram showing an example of the information processing device 5a according to the second embodiment. FIG. 23 is a functional explanatory diagram showing an example of the information processing device 5a according to the second embodiment.

As in the first embodiment, the information acquisition section 500 acquires cleaning conditions and drying conditions as finishing conditions. The cleaning conditions include substrate-holder state information, cleaning-fluid-supply-structure state information, and substrate-cleaning-structure state information. The drying conditions include substrate-holder state information and drying-fluid-supply-structure state information.

As described above, the state prediction section 501 inputs the cleaning conditions acquired by the information acquisition section 500 as the input data to the third learning model 10C, thereby predicting the cleaning quality information (in this embodiment, the cleaning degree information and the substrate defect information) for the wafer W on which the cleaning process is performed under the cleaning conditions. Furthermore, as described above, the state prediction section 501 inputs the drying conditions acquired by the information acquisition section 500 as the input data to the fourth learning model 10D, thereby predicting the drying quality information (in this embodiment, the drying degree information and the substrate defect information) for the wafer W on which the drying process is performed under the drying conditions.

As described above, the information processing device 5 and the information processing method according to the present embodiment input the cleaning conditions including the substrate-holder state information, the cleaning-fluid-supply-structure state information, and the substrate-cleaning-structure state information in the cleaning process to the third learning model 10C, and predict the substrate state information (cleaning quality information) for the cleaning conditions, so that the state of the wafer W during or after the cleaning process can be appropriately predicted. Furthermore, the information processing device 5 and the information processing method according to the present embodiment input the drying conditions including the substrate-holder state information and the drying-fluid-supply-structure state information in the drying process to the fourth learning model 10D, and predict the substrate state information (drying quality information) for the drying conditions, so that the state of the wafer W during or after the drying process can be appropriately predicted.

### Third Embodiment

A third embodiment differs from the first embodiment in that the learning model is constituted of a learning model for stress analysis and a learning model for finishing-quality analysis. In this embodiment, a machine-learning device 4b and an information processing device 5b according to the third embodiment will be described, focusing on differences from the first embodiment.

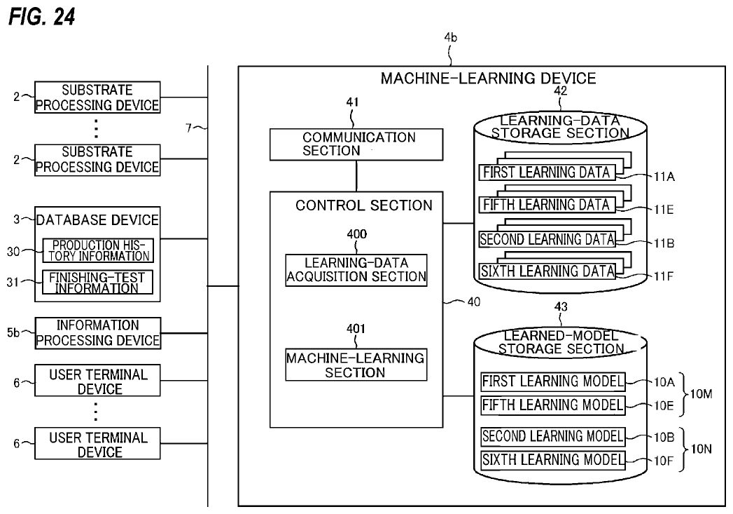

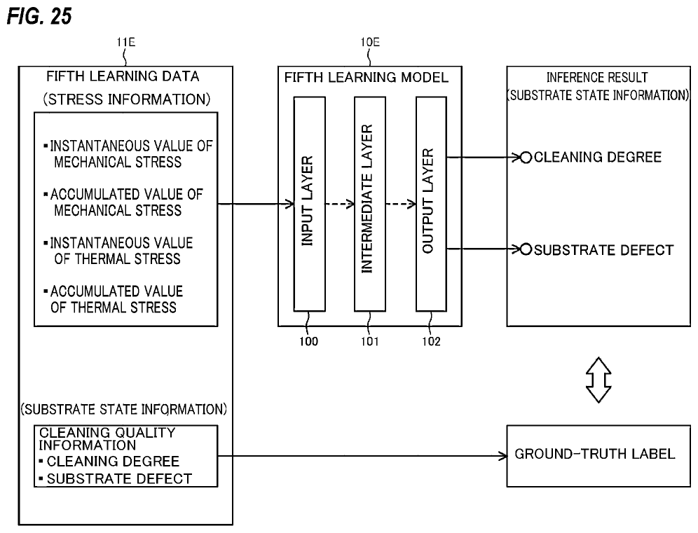

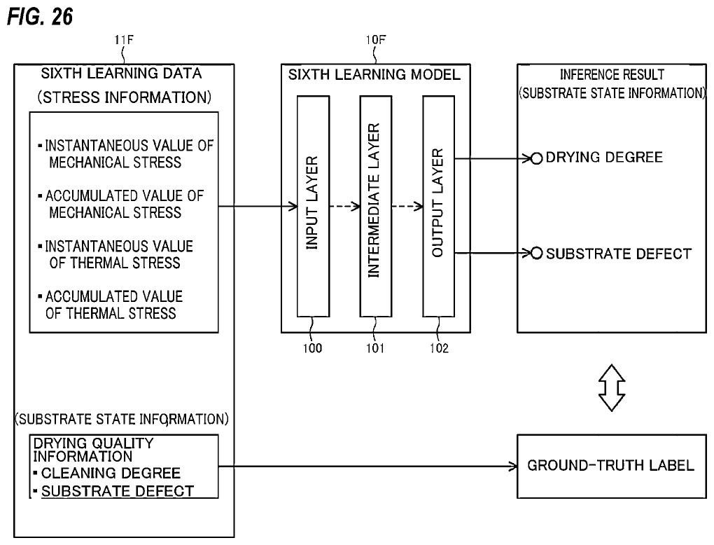

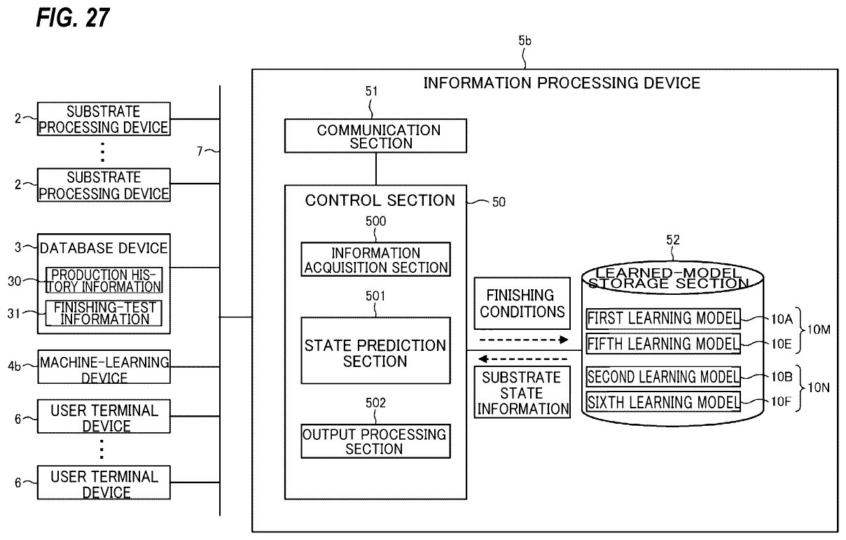

FIG. 24 is a block diagram showing an example of the machine-learning device 4b according to the third embodiment. FIG. 25 is a diagram showing an example of a fifth learning model 10E and fifth learning data 11E for cleaning-quality analysis. FIG. 26 is a diagram showing an example of a sixth learning model 10F and sixth learning data 11F for drying-quality analysis.

A learning model 10M for the cleaning process is composed of the first learning model 10A for the stress analysis (FIG. 13) and the fifth learning model 10E for the cleaning-quality analysis (FIG. 25). The fifth learning data 11E used for machine learning of the fifth learning model 10E for the cleaning-quality analysis is composed of stress information and cleaning quality information (in this embodiment, cleaning degree information and substrate defect information) as shown in FIG. 25. A learning model 10N for the drying process is composed of the second learning model 10B for the stress analysis (FIG. 14) and the sixth learning model 10F for the drying-quality analysis (FIG. 26). The sixth learning data 11F used for machine learning of the sixth learning model 10F for the drying-quality analysis is composed of stress information and drying quality information (in this embodiment, drying degree information and substrate defect information) as shown in FIG. 26. The first and second learning models 10A, 10B for the stress analysis and the first and second learning data 11A, 11B are configured in the same manner as in the first embodiment (FIGS. 13 and 14), and therefore descriptions thereof will be omitted.

The learning data acquisition section 400 acquires the fifth learning data 11E constituted of the stress information and the cleaning quality information and the sixth learning data 11F constituted of the stress information and the drying quality information by referring to the finishing-test information 31 and receiving, as necessary, the input manipulations of the user through the user terminal device 6.

The machine learning section 401 inputs multiple sets of the fifth learning data 11E to the fifth learning model 10E for the finishing quality analysis, and causes the fifth learning model 10E for the finishing quality analysis to learn a correlation between the stress information and the cleaning quality information contained in the fifth learning data 11E, thereby generating the fifth learning model 10E as a learned model for the finishing quality analysis. Furthermore, the machine learning section 401 inputs multiple sets of the sixth learning data 11F to the sixth learning model 10F, and causes the sixth learning model 10F learn a correlation between the stress information and the drying quality information contained in the sixth learning data 11F, thereby generating the sixth learning model 10F as a learned model.

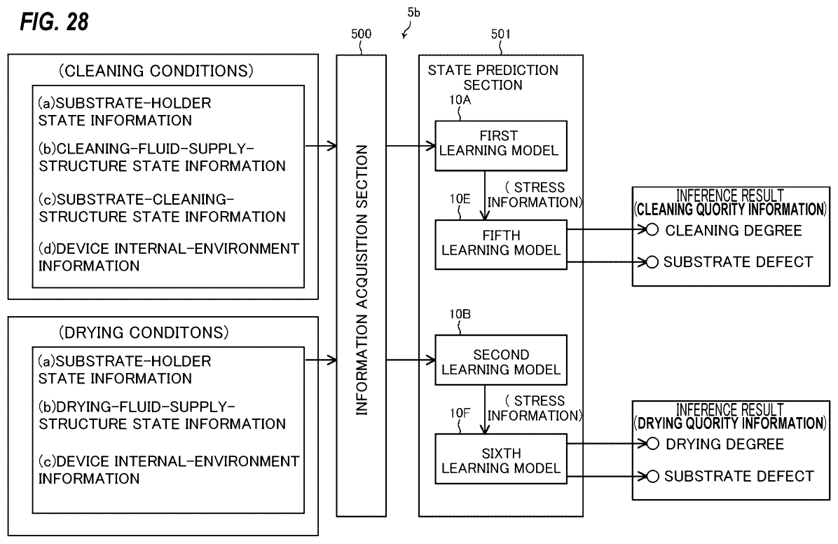

FIG. 27 is a block diagram showing an example of an information processing device 5b according to the third embodiment. FIG. 28 is a functional explanatory diagram showing an example of the information processing device 5b according to the third embodiment.

As in the first embodiment, the information acquisition section 500 acquires cleaning conditions including substrate-holder state information, cleaning-fluid-supply-structure state information, and substrate-cleaning-structure state information, and further acquires drying conditions including substrate-holder state information and drying-fluid-supply-structure state information.

As described above, the state prediction section 501 inputs the cleaning conditions acquired by the information acquisition section 500 as input data into the first learning model 10A, thereby predicting stress information for the wafer W subjected to the cleaning process under the cleaning conditions, and inputs the predicted stress information as input data into the fifth learning model 10E, thereby predicting cleaning quality information (in this embodiment, cleaning degree information and substrate defect information) for the wafer W that receives the stress indicated by the stress information. Furthermore, as described above, the state prediction section 501 inputs the drying conditions acquired by the information acquisition section 500 as input data into the second learning model 10B, thereby predicting stress information for the wafer W subjected to the drying process under the drying conditions, and inputs the predicted stress information as input data into the sixth learning model 10F, thereby predicting drying quality information (in this embodiment, drying degree information and substrate defect information) for the wafer W that receives the stress indicated by the stress information.

As described above, the information processing device 5b and the information processing method of this embodiment input the cleaning conditions in the cleaning process into the learning model 10M for the cleaning process (the first and fifth learning models 10A, 10E), and predict the substrate state information (the cleaning quality information) for the cleaning conditions, so that the state of the wafer W during or after the cleaning process can be appropriately predicted. Furthermore, the information processing device 5b and the information processing method of this embodiment input the drying conditions in the drying process into the learning model 10N for the drying process (the second and sixth learning models 10B, 10F), and predict the substrate state information (the drying quality information) for the drying conditions, so that the state of the wafer W during or after the drying process can be appropriately predicted.

### Other Embodiments

The present invention is not limited to the above-described embodiments, and various modifications can be made and used without deviating from the scope of the present invention. All of them are included in the technical concept of the present invention.

In the above-described embodiments, the database device 3, the machine-learning device 4, 4a, 4b, and the information processing device 5, 5a, 5b are described as being configured as separate devices, but these three devices may be configured as a single device. In one embodiment, any two of these three devices may be configured as a single device. Further, at least one of the machine-learning device 4, 4a, 4b, and the information processing device 5, 5a, 5b may be incorporated into the control unit 26 of the substrate processing device 2 or the user terminal device 6.

In the above embodiment, the substrate processing device 2 has been described as including the units 21 to 25, but the substrate processing device 2 may have at least one of the function of performing the cleaning process as the substrate cleaning device (the roll-sponge cleaning sections 24A, 24B or pen-sponge cleaning sections 24C, 24D) and the function of performing the drying process as the substrate drying device (the drying sections 24E, 24F) among the finishing unit 24, and the other units may be omitted.

In the above embodiment, the machine-learning devices 4, 4a, 4b and the information processing devices 5, 5a, 5b have been described as operating for the substrate cleaning device that performs the roll sponge cleaning using the roll sponges 2400 (the roll sponge cleaning units 24A, 24B) or the pen sponge cleaning using the pen sponge 2401 (the pen sponge cleaning units 24C, 24D), but the substrate cleaning device is not limited to the above examples. For example, the substrate cleaning device may perform buff cleaning using a buff as a cleaning tool, or may not have a cleaning tool and perform a cleaning process using a substrate cleaning fluid or using an ultrasonic cleaner. In addition, if the substrate cleaning device does not have a cleaning tool, the substrate cleaning conditions may not include the substrate-cleaning-structure state information.

In the embodiments described above, the neural network is employed as the learning model that implements the machine learning performed by the machine-learning section 401, while any other machine-learning model may be employed. Examples of the other machine-learning model include tree type (e.g., decision tree, regression tree), ensemble learning (e.g., bagging, boosting), neural network type including deep learning (e.g., recurrent neural network, convolutional neural network, LSTM), clustering type (e.g., hierarchical clustering, non-hierarchical clustering, k-nearest neighbor algorithm, k-means clustering), multivariate analysis (e.g., principal component analysis, factor analysis, logistic regression), and support vector machine.

In the above embodiment, the various information included in the finishing conditions (the cleaning conditions, the drying conditions) which are input data for the first to fourth learning models 10A to 10D has been described. Further, it has been described that the first to fourth learning models 10A to 10D may be prepared for each type of wafer W. The finishing conditions may further include unprocessed substrate information indicating a state (i.e., an initial state) of an unprocessed substrate, which is a wafer W before the finishing process. The unprocessed substrate information included in the finishing conditions includes at least one of a shape (e.g., a size, a thickness, a warp, etc.), a weight, and a condition of a substrate surface of the unprocessed substrate. The condition of the substrate surface is, for example, information on a degree and presence or absence of defect formed in the substrate surface, and information on size, an in-plane distribution, and the number of particles adhering to the substrate surface, while the information is not limited to these examples as long as information affects the finishing process. The unprocessed substrate information may be acquired, for example, from operation information of a device in a previous process (including the polishing unit 22), or may be measured by the film-thickness measuring unit 25, or other measuring device (e.g., an optical sensor, a contact sensor, a weight sensor, etc.) installed inside or outside the substrate processing device 2. The unprocessed substrate information acquired or measured as described above may be used for other unprocessed substrates in the same lot, or may be used for other unprocessed substrates in another lot.

In the learning phase of the machine learning, the unprocessed substrate information is registered in the finishing-test information 31, and is acquired as a part of the finishing conditions by the machine-learning devices 4, 4a, 4b. The machine-learning devices 4, 4a, 4b perform the machine learning for the first to fourth learning models 10A to 10D using the first to fourth learning data 11A to 11D, which are constituted of the finishing conditions further including the unprocessed substrate information, and the substrate state information.

In the inference phase of the machine learning, the unprocessed substrate information is acquired as a part of the finishing conditions by the information processing devices 5, 5a, 5b. The information processing devices 5, 5a, 5b input the finishing conditions further including the unprocessed substrate information as the input data to the first to fourth learning data 11A to 11D, thereby predicting the substrate state information when the finishing process is performed on the unprocessed substrate under the finishing conditions.

### (Machine Learning Program and Information Processing Program)

The present invention can be provided in a form of a program (machine learning program) that causes the computer 900 to function as each section of the machine-learning devices 4, 4a, and 4b, and in a form of a program (machine learning program) that causes the computer 900 to execute each process of the machine-learning method. Further, the present invention can be provided in a form of a program (information processing program) that causes the computer 900 to function as each section included in the information processing devices 5, 5a, and 5b, and in a form of a program (information processing program) that causes the computer 900 to execute each process of the information processing method according to the above-described embodiments.

### (Inference Apparatus, Inference Method, and Inference Program)

The present invention can be provided not only in a form of the information processing devices 5, 5a, and 5b (information processing method or information processing program) according to the above-described embodiments, but also in a form of an inference apparatus (inference method or information processing program) used for inferring the substrate state information. In that case, the inference apparatus (inference method or inference program) may include a memory and a processor. The processor may execute a series of processes. The series of processes includes an information acquisition processing (information acquisition process) of acquiring the finishing conditions, and an inference processing (inference process) of inferring the substrate state information (stress information or finishing quality information) indicating the state of the substrate on which the finishing process is performed under the finishing conditions when acquiring the finishing conditions in the information acquisition processing. The series of processing further includes an information acquisition processing (information acquisition process) of acquiring the stress information, and an inference processing (inference process) of inferring the finishing quality information indicating the finishing quality of the substrate to which the stress indicated by the stress information is applied when acquiring the stress information in the information acquisition processing.

The form of the inference apparatus (inference method or inference program) can be applied to various devices more easily than when the information processing device is implemented. It is readily understood by a person skilled in the art that the state prediction section may be applied with use of the learning model as the learned model created by the machine-learning device and the machine-learning method according to the above-described embodiments when the inference apparatus (inference method or inference program) infers the substrate state information.

### INDUSTRIAL APPLICABILITY

The present invention is applicable to an information processing apparatus, an inference apparatus, a machine-learning device, an information processing method, an inference method, and a machine-learning method.

### REFERENCE SIGNS LIST

1 . . . substrate processing system, 2 . . . substrate processing device,
3 . . . database device, 4, 4a, 4b . . . machine-learning device,
5, 5a, 5b . . . information processing device, 6 . . . user terminal device, 7 . . . network,
10A . . . first learning model, 10B . . . second learning model,
10C . . . third learning model, 10D . . . fourth learning model,
10E . . . fifth learning model, 10F . . . sixth learning model,
10M . . . learning model, 10N . . . learning model,
11A . . . first learning data, 11B . . . second learning data,
11C . . . third learning data, 11D . . . fourth learning data,
11E . . . fifth learning data, 11F . . . sixth learning data,
20 . . . housing, 21 . . . load-unload unit,
22 . . . polishing unit, 22A-22D . . . polishing section, 23 . . . substrate transport unit,
24 . . . finishing unit, 24A, 24B . . . roll-sponge cleaning section,
24C, 24D . . . pen-sponge cleaning section, 24E, 24F . . . drying section
24G, 24H . . . transporting section
25 . . . film-thickness measuring unit, 26 . . . control unit,
30 . . . production history information, 31 . . . finishing-test information,
40 . . . control section, 41 . . . communication section, 42 . . . learning-data storage section,
43 . . . learned-model storage section,
50 . . . control section, 51 . . . communication section, 52 . . . learned-model storage section,
240 . . . substrate cleaning structure, 241 . . . substrate holder,
242 . . . cleaning-fluid supply structure, 243 . . . cleaning-tool cleaning structure,
244 . . . environment sensor, 245 . . . drying-fluid supply structure,
260 . . . control section, 21 . . . communication section, 262 . . . input section, 263 . . . output section,
264 . . . memory section, 300 . . . wafer history table, 301 . . . cleaning history table,
302 . . . drying history table, 310 . . . cleaning-test table, 311 . . . drying-test table,
400 . . . learning-data acquisition section, 401 . . . machine-learning section,
500 . . . information acquisition section, 501 . . . state prediction section,
502 . . . output processing section, 900 . . . computer, 2200 . . . polishing pad, 2230 . . . dresser disk,
2400 . . . roll sponge, 2401 . . . pen sponge

1. An information processing apparatus comprising:
an information acquisition section configured to acquire finishing conditions including substrate-holder state information indicating a state of a substrate holder and a finishing-fluid-supply-structure state information indicating a state of a finishing-fluid supply structure in a finishing process of a substrate performed by a substrate processing apparatus including the substrate holder configured to hold the substrate and the finishing-fluid supply structure configured to supply a substrate finishing fluid onto the substrate; and
a state prediction section configured to predict substrate state information for the substrate on which the finishing process is performed under the finishing conditions by inputting the finishing conditions acquired by the information acquisition section to a learning model that has been generated by machine learning that causes the learning model to learn a correlation between the finishing conditions and substrate state information indicating a state of the substrate on which the finishing process is performed under the finishing conditions, the substrate state information comprising stress information indicating stress applied to the substrate.

2. The information processing apparatus according to claim 1, wherein the substrate holder includes:
a substrate rotating mechanism configured to rotate the substrate about a first rotation axis perpendicular to a finishing-target surface of the substrate; and
a substrate holding mechanism configured to hold a side edge of the substrate,
the substrate-holder state information included in the finishing conditions includes at least one of:
the number of holding points at which the substrate holding mechanism holds the substrate;
a holding pressure at which the substrate holding mechanism holds the substrate;
a rotation speed of the substrate rotating mechanism;
a rotation torque of the substrate rotating mechanism; and
a condition of the substrate holding mechanism.

3. The information processing apparatus according to claim 1, wherein the finishing-fluid-supply-structure state information included in the finishing conditions includes at least one of:
a flow rate of the substrate finishing fluid;
a pressure of the substrate finishing fluid;
a dropping position of the substrate finishing fluid;
a temperature of the substrate finishing fluid; and
a concentration of the substrate finishing fluid.

4. The information processing apparatus according to claim 1, wherein the finishing conditions further include device internal-environment information indicating an environment of a space in which the finishing processing is performed, and the device internal-environment information included in the finishing conditions includes at least one of:
a temperature in the space;
a humidity in the space;
an atmospheric pressure of the space;
an airflow in the space;
an oxygen concentration in the space; and
sound in the space.

5. The information processing apparatus according to claim 1, wherein the finishing conditions further include unprocessed substrate information indicating a state of an unprocessed substrate which is the substrate before the finishing process is performed.

6. The information processing apparatus according to claim 5, wherein the unprocessed substrate information included in the finishing conditions includes at least one of:
a shape of the unprocessed substrate;
a weight of the unprocessed substrate; and
a condition of a substrate surface of the unprocessed substrate.

7. The information processing apparatus according to claim 1, wherein the finishing conditions comprise cleaning conditions in a cleaning process of the substrate performed as the finishing process by the substrate processing apparatus.

8. The information processing apparatus according to claim 7, wherein the substrate processing apparatus further comprises a substrate cleaning structure configured to rotatably support a cleaning tool and bring the cleaning tool into contact with the substrate to clean the substrate, and
the cleaning conditions further include substrate-cleaning-structure state information indicating a state of the substrate cleaning structure.

9. The information processing apparatus according to claim 8, wherein the substrate cleaning structure includes:
a cleaning-tool rotating mechanism configured to rotate the cleaning tool about a second rotation axis parallel to a cleaning-target surface of the substrate or about a third rotation axis perpendicular to the cleaning-target surface; and
a cleaning-tool moving mechanism configured to move a relative position of the cleaning tool and the cleaning-target surface, and
the substrate-cleaning-structure state information included in the finishing conditions includes at least one of:
a rotation speed of the cleaning-tool rotating mechanism;
a rotation torque of the cleaning-tool rotating mechanism;
position coordinates of the cleaning-tool moving mechanism;
a movement speed of the cleaning-tool moving mechanism;
a movement torque of the cleaning-tool moving mechanism;
a pressing load at which the cleaning tool is brought into contact with the substrate, and
a condition of the cleaning tool.

10. The information processing apparatus according to claim 1, wherein the finishing conditions comprise drying conditions in a cleaning process of the substrate performed as the finishing process by the substrate processing apparatus.

11. The information processing apparatus according to claim 1, wherein
the stress information indicates at least one of mechanical stress and thermal stress applied to the substrate.

12. The information processing apparatus according to claim 11, wherein the stress information indicates:
an instantaneous value of the stress at a target point-in-time included in a finishing-process period from start to end of the finishing process; or
an accumulated value of the stress in a target period from the start of the finishing process to the target point-in-time.

13. The information processing apparatus according to claim 11, wherein the stress information indicates an in-plane distribution state of the stress applied to a substrate surface of the substrate.

14. The information processing apparatus according to claim 7, wherein the substrate state information comprises finishing quality information indicating a finishing quality of the substrate, and
the finishing quality information comprises cleaning quality information indicating a cleaning quality of the substrate in the cleaning process.

15. The information processing apparatus according to claim 10, wherein the substrate state information comprises finishing quality information indicating a finishing quality of the substrate, and
the finishing quality information comprises drying quality information indicating a drying quality of the substrate in the drying process.

16. The information processing apparatus according to claim 1, wherein the learning model comprises:
a learning model for stress analysis that has been generated by machine learning that causes the learning model for stress analysis to learn a correlation between the finishing conditions and stress information indicating stress applied to the substrate on which the finishing process is performed under the finishing conditions; and
a learning model for finishing-quality analysis that has been generated by machine learning that causes the learning model for finishing-quality analysis to learn a correlation between the stress information and finishing quality information indicating a finishing quality of the substrate to which the stress indicated by the stress information is applied, and
the state prediction section is configured to:
predict the stress information for the substrate on which the finishing process under the finishing conditions is performed by inputting the finishing conditions acquired by the information acquisition section to the learning model for the stress analysis; and
predict the finishing quality information for the substrate to which the stress indicated by the stress information is applied by inputting the predicted stress information to the learning model for the finishing-quality analysis.

17. An inference apparatus comprising:
a memory; and
a processor configured to perform:
an information acquisition process of acquiring finishing conditions including substrate-holder state information indicating a state of a substrate holder and a finishing-fluid-supply-structure state information indicating a state of a finishing-fluid supply structure in a finishing process of a substrate performed by a substrate processing apparatus including the substrate holder configured to hold the substrate and the finishing-fluid supply structure configured to supply a substrate finishing fluid onto the substrate; and
an inference process of inferring substrate state information indicating a state of the substrate on which the finishing process is performed under the finishing conditions when the finishing conditions are acquired in the information acquisition process, the substrate state information comprising stress information indicating stress applied to the substrate.

18. An inference apparatus comprising:
a memory; and
a processor configured to perform:
an information acquisition process of acquiring stress information indicating stress applied to a substrate on which a finishing process is performed by a substrate processing apparatus including a substrate holder configured to hold the substrate and a finishing-fluid supply structure configured to supply a substrate finishing fluid onto the substrate; and
an inference process of inferring finishing quality information indicating a finishing quality of the substrate to which the stress indicated by the stress information is applied when the stress information is acquired in the information acquisition process.

19. A machine-learning apparatus comprising:
a learning-data storage section storing multiple sets of learning data including finishing conditions and substrate state information, the finishing conditions including substrate-holder state information indicating a state of a substrate holder and a finishing-fluid-supply-structure state information indicating a state of a finishing-fluid supply structure in a finishing process of a substrate performed by a substrate processing apparatus including the substrate holder configured to hold the substrate and the finishing-fluid supply structure configured to supply a substrate finishing fluid onto the substrate, the substrate state information indicating a state of the substrate on which the finishing process is performed under the finishing conditions the substrate state information comprising stress information indicating stress applied to the substrate;
a machine-learning section configured to cause a learning model to learn a correlation between the finishing conditions and the substrate state information by inputting the multiple sets of learning data to the learning model; and
a learned-model storage section configured to store the learning model that has learned the correlation by the machine-learning section.

20. A machine-learning apparatus comprising:
a learning-data storage section storing multiple sets of learning data including stress information and finishing quality information, the stress information indicating stress applied to a substrate on which a finishing process is performed by a substrate processing apparatus including a substrate holder configured to hold the substrate and a finishing-fluid supply structure configured to supply a substrate finishing fluid onto the substrate, the finishing quality information indicating a finishing quality of the substrate to which the stress indicated by the stress information is applied;
a machine-learning section configured to cause a learning model to learn a correlation between the stress information and the finishing quality information by inputting the multiple sets of learning data to the learning model; and
a learned-model storage section configured to store the learning model that has learned the correlation by the machine-learning section.

21. (canceled)

22. (canceled)

23. (canceled)

24. (canceled)

25. (canceled)
